(19) United States
(12) Patent Application Publication
(10) Pub. No.: US 2024/0402853 A1
(43) Pub. Date: Dec. 5, 2024

(54) ELECTRONIC DEVICE INCLUDING AN INPUT SENSOR

(71) Applicant: SAMSUNG DISPLAY CO., LTD., Yongin-si (KR)

(72) Inventors: JUNSU PARK, Yongin-si (KR); Bohwa Kim, Yongin-si (KR); Dong-Hyun Gong, Yongin-si (KR); Moonsung Kim, Yongin-si (KR)

(21) Appl. No.: 18/617,457

(22) Filed: Mar. 26, 2024

(30) Foreign Application Priority Data
May 30, 2023 (KR) 10-2023-0069129

(51) Int. Cl. G06F 3/044; H10K 59/131; H10K 59/40; H10K 59/80

(52) U.S. Cl. CPC G06F 3/0446; H10K 59/131; H10K 59/40; H10K 59/873

(57) ABSTRACT

An electronic device includes a base layer, a circuit layer disposed on the base layer and including a transistor, a plurality of inorganic films, and a plurality of organic films. A display element layer is disposed on the circuit layer. An encapsulation layer is disposed on the display element layer. An input sensor is disposed on the encapsulation layer and includes a sensor base layer, a sensor conductive layer disposed on the sensor base layer, and a sensor insulating layer disposed on the sensor base layer and including silicon nitride (SiNx). The sensor base layer includes a buffer insulating layer including silicon (Si) and oxygen (O), and an atomic percent of oxygen (O) in the buffer insulating layer is in a range of 2 at % to 67 at %.

### CROSS-REFERENCE TO RELATED APPLICATIONS

This application claims priority under 35 U.S.C. § 119 to Korean Patent Application No. 10-2023-0069129, filed on May 30, 2023, in the Korean Intellectual Property Office, the disclosure of which is incorporated by reference herein in its entirety.

### TECHNICAL FIELD

The present disclosure described relates to an electronic device, and more particularly, to an electronic device including an input sensor.

### DISCUSSION OF THE RELATED ART

Multimedia electronic devices, such as a television (TV), a cellular phone, a tablet computer, a navigation system, a portable game console, and a game controller, may provide a touch-based input manner for enabling a user to intuitively, and conveniently input information or a command, while displaying an image through a display screen. The electronic device may include a display panel to generate an image and an input sensor to sense the touch of the user.

The display panel and the input sensor may include a plurality of stack structures, and the stack structures may include a structure in which an organic film and an inorganic film are stacked. When the bonding force between the organic film and the inorganic film is not sufficient in the stack structure, the durability of the electronic device may be degraded.

### SUMMARY

An electronic device includes a base layer, A circuit layer is disposed on the base layer and includes a transistor, a plurality of inorganic films, and a plurality of organic films. A display element layer is disposed on the circuit layer. An encapsulation layer is disposed on the display element layer. An input sensor is disposed on the encapsulation layer and includes a sensor base layer, a sensor conductive layer disposed on the sensor base layer, and a sensor insulating layer disposed on the sensor base layer and including silicon nitride (SiNx). The sensor base layer includes a buffer insulating layer including silicon (Si) and oxygen (O), and an atomic percent of oxygen (O) within the buffer insulating layer is in a range of 2 at % to 67 at %.

The sensor base layer may further include a base insulating layer including silicon nitride (SiNx), and the base insulating layer is disposed directly on the buffer insulating layer.

The base insulating layer may further include oxygen (O), and the buffer insulating layer further include nitrogen (N), and an atomic percent of oxygen (O) in the buffer insulating layer may be 2 to 100 times an atomic percent of oxygen (O) in the base insulating layer.

The sensor base layer may have a thickness ranging from 1000 Å to 3000 Å, and the buffer insulating layer may have a thickness ranging from 150 Å to 3000 Å.

The base insulating layer and the buffer insulating layer may be formed through a chemical vapor deposition (CVD) scheme, and a first power used to form the buffer insulating layer is 35% or less of a second power used to form the base insulating layer.

The buffer insulating layer may have a porosity that is higher than a porosity of the base insulating layer.

The sensor base layer may be a single layer of the buffer insulating layer including silicon dioxide (SiO₂).

The sensor base layer may be a single layer of the buffer insulating layer including the silicon nitride (SiN_{X}) and oxygen (O).

The electronic device may further include an active region and a peripheral region defined in at least one side of the active region. The peripheral region may include a signal line electrically connected to the transistor, an inorganic film pattern may be formed on a same layer as one of the inorganic films is formed on, and the inorganic film pattern has a groove defined in the inorganic film pattern, the signal line may be disposed in the groove. An organic film pattern may be formed on a same layer as one of the organic films is formed on. The organic film pattern may cover an edge of the signal line, not overlapping with the groove. The sensor conductive layer may be electrically connected to the signal line in the groove, and the sensor base layer may be disposed under the sensor conductive layer, and the sensor base layer may overlap with the organic film pattern, a top surface of the signal line, and the inorganic film pattern.

The sensor base layer may further include a base insulating layer including silicon nitride (SiNx), and the buffer insulating layer may be interposed directly between the organic film pattern and the base insulating layer.

The base insulating layer may further include oxygen (O) and carbon (C), the buffer insulating layer may further include nitrogen (N) and carbon (C), the atomic percent of oxygen (O) in the buffer insulating layer may be 2 to 100 times the atomic percent of oxygen (O) in the base insulating layer, and the atomic percent of carbon (C) in the buffer insulating layer may be 2 to 100 times the atomic percent of carbon (C) in the base insulating layer.

The buffer insulating layer may be interposed directly between the organic film pattern and the sensor insulating layer.

The sensor insulating layer and the buffer insulating layer may further include carbon (C), and the atomic percent of carbon (C) in the buffer insulating layer may be 2 to 100 times the atomic percent of carbon (C) in the sensor insulating layer.

The encapsulation layer may include a first inorganic layer sequentially stacked on the display element layer, an organic layer disposed on the first inorganic layer a second inorganic layer disposed on the organic layer and including silicon nitride (SiNx), and an intermediate layer interposed directly between the organic layer and the second inorganic layer and including silicon (Si), nitrogen (N), oxygen (O), and carbon (C).

The second inorganic layer may further include oxygen (O) and carbon (C), the atomic percent of oxygen (O) in the intermediate layer may be 2 to 100 times the atomic percent of oxygen (O) in the second inorganic layer, and the atomic percent of carbon (C) in the intermediate layer may be 2 to 100 times the atomic percent of carbon (C) in the second inorganic layer.

The sensor base layer may be disposed directly on the second inorganic layer.

An electronic device includes an active region and a peripheral region disposed on at least one side of the active region. The peripheral region includes a base layer, a circuit layer disposed on the base layer, and the circuit layer includes an inorganic film pattern having a groove defined therein. A signal line is disposed in the groove. An organic film pattern covers an edge of the signal line and exposes a portion of a top surface of the inorganic film pattern. An input sensor is disposed on the circuit layer. The input sensor includes a sensor conductive layer electrically connected to the signal line, a sensor base layer covering the organic film pattern and the exposed top surface of the inorganic film pattern, and a sensor insulating layer disposed on the sensor base layer. The sensor base layer includes a buffer insulating layer including silicon (Si) and oxygen (O), and an atomic percent of oxygen (O) in the buffer insulating layer is in a range of 2 at % to 67 at %.

The sensor base layer may include SiNx and may further include a base insulating layer disposed under the sensor insulating layer, and the base insulating layer may be disposed directly on the buffer insulating layer.

The sensor base layer may have a thickness ranging from 1000 Å to 3000 Å, and the buffer insulating layer may have a thickness ranging from 150 Å to 3000 Å.

The base insulating layer may further include oxygen (O) and carbon (C), and the buffer insulating layer may further include nitrogen (N), and carbon (C), the atomic percent of oxygen (O) in the buffer insulating layer may be 2 to 100 times the atomic percent of oxygen (O) in the base insulating layer, and the atomic percent of carbon (C) in the buffer insulating layer may be 2 to 100 times the atomic percent of carbon (C) in the base insulating layer

The sensor base layer may be a single layer including the buffer insulating layer, and the buffer insulating layer may include SiO₂ or includes SiN_{X} and O.

The active region may further include a display element layer interposed between the circuit layer and the input sensor, and the display element layer includes a light emitting element; and an encapsulation layer disposed on the display element layer; and the sensor base layer may be disposed directly on the encapsulation layer in the active region.

In the active region, the circuit layer may include an inorganic film formed in a same process as the inorganic film pattern, an organic film formed in a same process as the organic film pattern, and a transistor electrically connected to the signal line.

An electronic device includes a base layer, a circuit layer disposed on the base layer and including a transistor, a plurality of inorganic films, and a plurality of organic films. A display element layer is disposed on the circuit layer. An encapsulation layer is disposed on the display element layer. An input sensor is disposed on the encapsulation layer and includes a sensor base layer, a sensor conductive layer disposed on the sensor base layer, and a sensor insulating layer disposed on the sensor base layer and including silicon nitride (SiNx). The sensor base layer includes a buffer insulating layer including silicon (Si) and oxygen (O), and the buffer insulating layer has a porosity that is higher than a porosity of the sensor insulating layer.

The sensor base layer may further include a base insulating layer disposed directly over the buffer insulating layer and including SiNx, and the porosity of the buffer insulating layer may be greater than a porosity of the sensor base layer.

The base insulating layer and the buffer insulating layer may be formed through a chemical vapor deposition (CVD) scheme and a first power used to form the buffer insulating layer may be 35% or less of a second power used to form the base insulating layer.

The base insulating layer may further include oxygen (O), and the buffer insulating layer may further includes nitrogen (N), and the atomic percent of oxygen (O) in the buffer insulating layer may be 2 to 100 times the atomic percent of oxygen (O) in the base insulating layer.

The sensor base layer may have a thickness ranging from 1000 Å to 3000 Å, and the buffer insulating layer may have a thickness ranging from 150 Å to 3000 Å.

### BRIEF DESCRIPTION OF THE FIGURES

The above and other objects and features of the present disclosure will become apparent by describing in detail embodiments thereof with reference to the accompanying drawings.

FIG. 1 is a perspective view illustrating an electronic device according to an embodiment of the present disclosure.

FIG. 2 is an exploded perspective view of an electronic device according to an embodiment of the present disclosure.

FIG. 3 is a cross-sectional view illustrating a part corresponding to line I-I′ of FIG. 2.

FIG. 4 is a cross-sectional view of a display module according to an embodiment of the present disclosure.

FIG. 5 is a plan view of a display panel according to an embodiment of the present disclosure.

FIG. 6 is a plan view of an input sensor according to an embodiment of the present disclosure.

FIG. 7 is a cross-sectional view of a portion of a display module according to an embodiment of the present disclosure.

FIG. 8 is a cross-sectional view illustrating a portion of an input sensor.

FIG. 9 is a view schematically illustrating a part of FIG. 8.

FIG. 10 is a cross-sectional view illustrating a portion of an input sensor according to an embodiment of the present disclosure.

FIG. 11 is a cross-sectional view of a portion of a display module according to an embodiment of the present disclosure.

FIG. 12 is a cross-sectional view of a part taken along line III-III′ of FIG. 6.

FIG. 13A is a view illustrating a portion of a peripheral region in a display module according to an embodiment of the present disclosure.

FIG. 13B is a view schematically illustrating a region ZZ of FIG. 13A.

FIG. 14A is a view illustrating a part of a peripheral region in a conventional display module.

FIG. 14B is a view schematically illustrating region ZZ′ of FIG. 14A.

FIG. 15 is a graph illustrating a material composition in a part of a display module according to an embodiment of the present disclosure.

### DETAILED DESCRIPTION

While the present disclosure is susceptible to various modifications and alternative forms, specific embodiments thereof are shown by way of examples in the drawings and will herein be described in detail. It should be understood, however, that the present disclosure is not necessarily limited to the particular forms disclosed, but on the contrary, the present disclosure is to cover all modifications, equivalents, and alternatives falling within the spirit and scope of the present disclosure.

In the specification, the expression that a first component (or region, layer, part, portion, etc.) is “on”, “connected to”, or “coupled to” a second component means that the first component is directly on, connected to, or coupled to the second component or means that a third component is interposed therebetween.

The same reference numeral may refer to the same component throughout the drawings and the disclosure. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. The expression “and/or” includes one or more combinations which associated components are capable of defining.

Although the terms “first”, “second”, etc. may be used to describe various components, the components should not necessarily be construed as being limited by the terms. The terms are used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, etc. are used to describe the correlation of components illustrated in drawings. The terms that are relative in concept are described based on a direction shown in drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

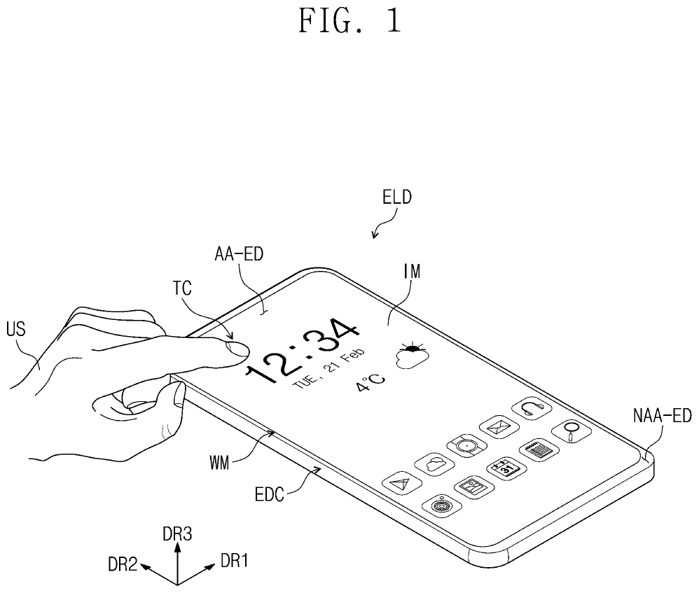

Hereinafter, the electronic apparatus according to an embodiment of the present disclosure will be described with reference to FIGS. 1-5.

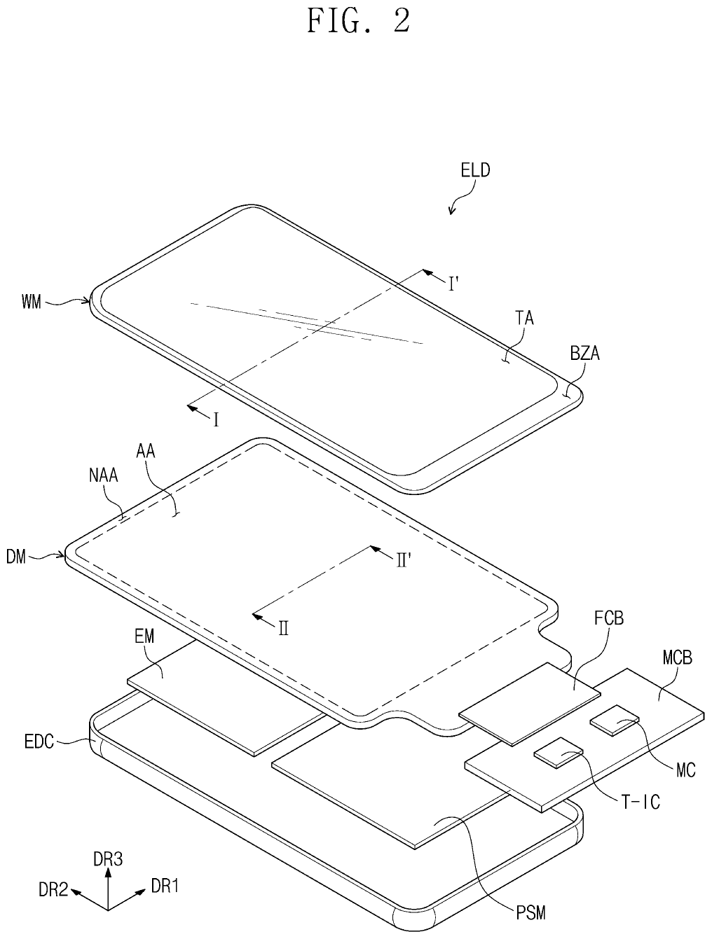

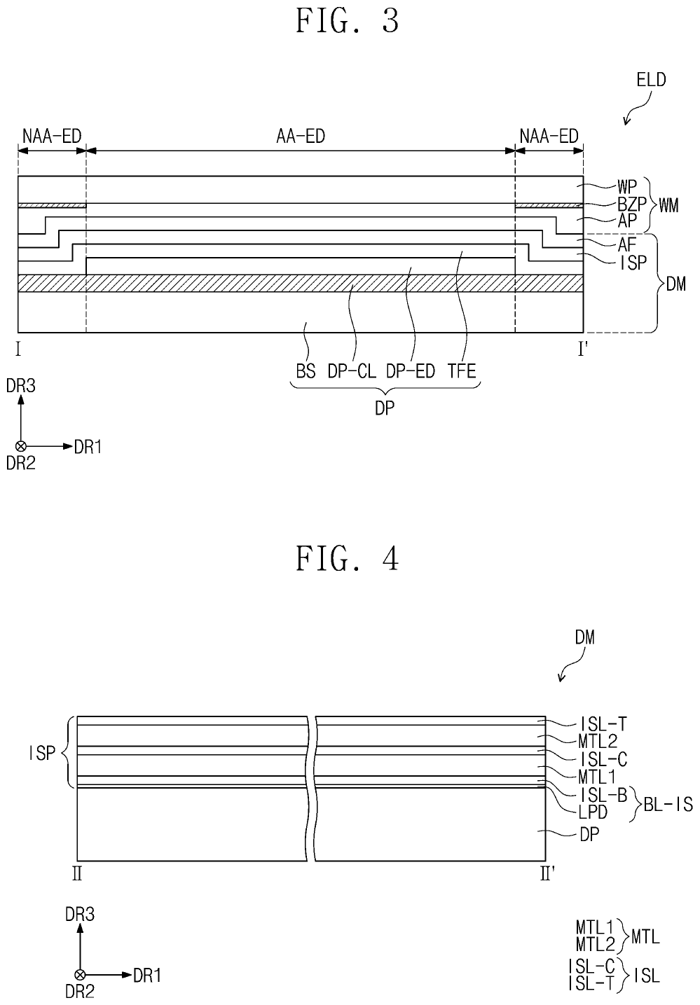

FIG. 1 is a perspective view illustrating an electronic device according to an embodiment of the present disclosure. FIG. 2 is an exploded perspective view illustrating an electronic device according to an embodiment of the present disclosure. FIG. 3 is a cross-sectional view illustrating an electronic device according to an embodiment of the present disclosure. FIG. 3 is a cross-sectional view illustrating a part corresponding to line I-I′ of FIG. 2.

Referring to FIG. 1, an electronic device ELD may be a device activated in response to an electrical signal to display an image. According to an embodiment of the present disclosure, the electronic device ELD may be a small and medium-sized electronic device, such as a computer monitor, a cellular phone, a tablet PC, a navigation system, a game console, or the like, as well as a large-sized electronic device, such as a television, or an external digital billboard. However, embodiments of the electronic device ELD are provided only for the illustrative purpose, and the electronic device ELD is not necessarily limited to any one embodiment unless departing from the scope and spirit of the invention.

The electronic device ELD may be rigid or flexible. The term “flexible” refers to a bendable characteristic such as one that might be bend to a noticeable degree without cracking or otherwise sustaining damage. For example, the flexible electronic device ELD may include a curved device, a rollable device, or a foldable device.

FIG. 1 and drawings thereafter illustrate the first to third directional axes (or directions) DR1 to DR3, and directions indicated by the first to third directional axes DR1 to DR3 described in this specification may be relative concepts and may be converted into other directions. In addition, the directions indicated by the first to third direction axes DR1, DR2, and DR3 will be referred to as the first to third directions and will be assigned with the same reference numerals. In this specification, the first directional axis DR1 and the second directional axis DR2 may be perpendicular to each other. The third directional axis DR3 may be a direction normal to the plane defined by the first directional axis DR1 and the second directional axis DR2.

The thickness direction of the electronic device ELD may be parallel to the third direction axis DR3 which is a direction of a normal line to the plane defined by the first direction axis DR1 and the second direction axis DR2. In the specification, the front surface (or top surface) and the rear surface (or the bottom surface) of members constituting the electronic device ELD may be defined based on the third direction axis DR3. The front surface (or top surface) and the rear surface (bottom surface) of each of members constituting the electronic device ELD are opposite to each other in the third direction axis DR3, and a normal direction to the front surface and the rear surface may be actually parallel to the third direction axis DR3. The distance between the front surface and the rear surface defined in the third direction DR3 may correspond to the thickness of the member.

In this specification, the term “on the plane” or “in a plan view” may indicate a state viewed in the third direction DR3. In this specification, the term “in a cross-sectional view” may indicate a state viewed in the first direction DR1 or the second direction DR2. The directions indicated by the first to third directions DR1, DR2, and D3 are relative concepts and switched another direction.

According to an embodiment of the present disclosure, the electronic device ELD may display an image IM through an active region AA-ED. The active region AA-ED may include a plane defined by the first direction DR1 and the second direction DR2. The active region AA-ED may further include a curved surface bent from at least one of a plane defined by the first direction DR1 and the second direction DR2. The surface on which the image IM is displayed may correspond to the front surface of the electronic device ELD. The image IM may include a still image in addition to a dynamic image.

A peripheral region NAA-ED is adjacent to the active region AA-ED. The peripheral region NAA-ED may at least partially surround the active region AA-ED. Accordingly, the shape of the active region AA-ED may be substantially defined by the peripheral region NAA-ED. However, the shape is provided only for the illustrative purpose, and the peripheral region NAA-ED may be adjacent to only one side of the active region AA-ED or may be omitted. The electronic device ELD, according to an embodiment of the present disclosure, may include various shapes of active regions, and the present disclosure is not necessarily limited to any one embodiment of the present disclosure.

The electronic device ELD is in the shape of a rectangle having a pair of shorter sides extending in the first direction DR1 and a pair of longer sides extending in the second direction DR2 crossing the first direction DR1, when viewed in a plan view. However, an embodiment is not necessarily limited thereto, and the electronic device ELD may have various shapes, such as a circular shape or a polygon shape, when viewed in a plan view.

The electronic device ELD may sense an external input TC applied from the outside. The external input TC may include various types of inputs such as force, pressure, a temperature, or light. According to an embodiment of the present disclosure, the external input TC is a touch input by a hand of a user US applied to the front surface of the electronic device ELD. However, this is provided for the illustrative purpose. The external input TC may include all inputs to provide a change in capacitance. The region of the electronic device ELD to sense the external input TC is not necessarily limited to the front surface of the electronic device ELD. For example, the electronic device ELD may sense the external input TC of the user US applied to the side surface or the rear surface.

Referring to FIGS. 1 to 3, according to an embodiment of the present disclosure, the electronic device ELD includes a display module DM. The display module DM may be a component to generate an image and to sense an input applied from the outside. According to an embodiment of the present disclosure, the display module DM may include a display panel DP and an input sensor ISP disposed on the display panel DP. In addition, according to an embodiment of the present disclosure, the display module DM may further include an optical layer AF disposed on the input sensor ISP.

According to an embodiment of the present disclosure, the electronic device ELD may include a window module WM disposed on the display module DM. In addition, the electronic device ELD may further include an electronic module EM, a power supply module PSM, and a housing EDC.

According to an embodiment of the present disclosure, the display module DM may be defined with an active region AA and a peripheral region NAA. The active region AA may be activated in response to an electrical signal. The peripheral region NAA may be a region positioned adjacent to at least one side of the active region AA.

The active region AA may correspond to the active region AA-ED of the electronic device illustrated in FIG. 1. The peripheral region NAA may at least partially surround the active region AA. However, an embodiment is not necessarily limited thereto. According to an embodiment of the present disclosure, a portion of the peripheral region NAA may be omitted, which is different from that as illustrated in FIG. 2. The peripheral region NAA may correspond to the peripheral region NAA-ED of the electronic device illustrated in FIG. 1.

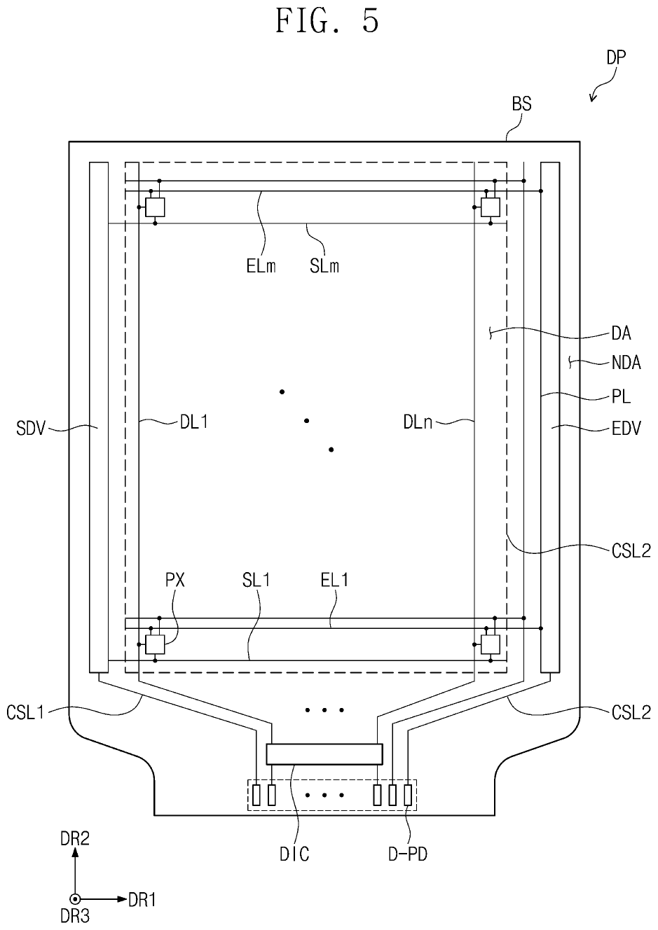

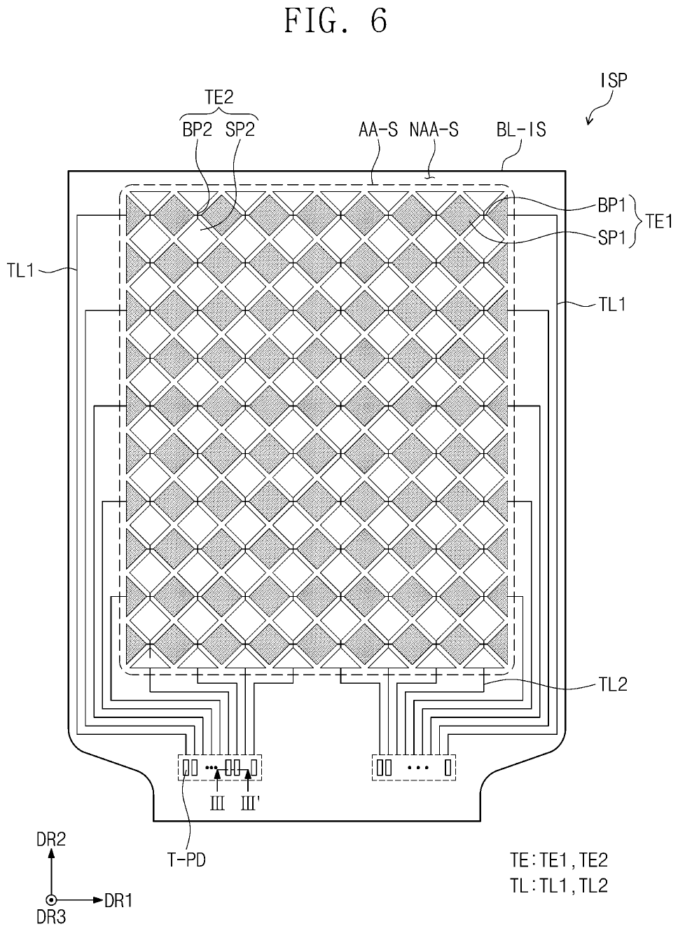

According to an embodiment of the present disclosure, the display module DM may include the peripheral region NAA disposed in at least one side of the active region AA. The region in which pads (see D-PD of FIG. 5; T-PD of FIG. 6) are disposed may be referred to as a pad region. The pad region may be a part of the peripheral region NAA. A driving circuit or driving line to drive the active region AA may be disposed in the pad region.

The window module WM may be disposed on the display module DM to protect the display module DM from an external impact or a scratch. The window module WM may cover an entire outer portion of the display module DM. The front surface of the window module WM may correspond to the top surface of the electronic device ELD.

According to an embodiment of the present disclosure, the window module WM may include a base member WP which is an insulating material that is optically transparent. The base member WP may include an insulating material which is optically transparent. The base member WP may include a glass member and/or a synthetic resin film. The base member WP may have a single-layer structure or a multi-layer structure formed by combining a plurality of films with each other. The window module WM may further include a functional layer, such as an anti-fingerprint layer, a phase control layer, or a hard coating layer disposed on the base member WP.

The window module WM may further include an adhesive layer AP. The base member WP and the display module DM may be combined with each other through the adhesive layer AP. However, the present disclosure is not necessarily limited thereto. The adhesive layer AP may be omitted. The window module WM may be disposed directly on the display module DM.

The window module WM may be classified into a transmission part TA and a bezel part BZA. The transmission part TA, which is a part corresponding to the active region AA of the display module DM, and the bezel part BZA may be a part corresponding to the peripheral region NAA of the display module DM. The bezel part BZA may define the shape of the transmission part TA. The bezel part BZA may be adjacent to the transmission part TA to at least partially surround the transmission part TA. However, the embodiment is not necessarily limited to the illustrated member. The bezel part BZA may be adjacent to only one side of the transmission part TA, and a portion of the bezel part BZA may be omitted.

The window module WM may further include a bezel pattern BZP corresponding to the bezel part BZA. The bezel pattern BZP may be a color layer formed on one surface of the base member WP. The bezel pattern BZP may include a material having a color. For example, the bezel pattern BZP may include a colored organic film. The bezel pattern BZP may have a single layer structure or a multi-layer structure. The bezel part BZA of the window module WM in which the bezel pattern BZP is disposed may have a light transmittance lower than that of the transmission part TA.

The display module DM may further include a main circuit board MCB, a flexible circuit film FCB, a data driver DIC, a sensor control circuit T-IC, and a main controller MC.

The main circuit board MCB may be electrically connected to the display module DM through the flexible circuit film FCB. The main circuit board MCB may be electrically connected to the electronic module EM through a connector.

The flexible circuit film FCB may be connected to the display panel DP and the input sensor ISP, respectively to electrically connect the display panel DP and the input sensor ISP to the main circuit board MCB. The input sensor ISP may be electrically connected to the display panel DP and may be electrically connected to the main circuit board MCB through the flexible circuit film FCB. However, the embodiment is not necessarily limited thereto. For example, the input sensor ISP may be electrically connected to the main circuit board MCB through the additional flexible circuit film, or the main circuit board MCB may be directly connected onto the display panel DP without the flexible circuit film FCB.

The data driver DIC, the sensor control circuit T-IC, and the main controller MC may be provided in the form of integrated chips. The data driver DIC may be mounted on the display module DM, and the sensor control circuit T-IC and the main controller MC may be mounted on the main circuit board MCB. However, the embodiment is not necessarily limited thereto. For example, the data driver DIC may be mounted on the flexible circuit film FCB.

The main controller MC may control the overall operation of the electronic device ELD. For example, the main controller MC may control the operations of the display panel DP and the input sensor ISP. In addition, the main controller MC may control the operation of the electronic module EM. The main controller MC may include at least one micro-processor.

The data driver DIC may include a driving circuit to drive pixels of the display panel DP. The data driver DIC may receive image data and a control signal from the main controller MC. For example, the control signal may include an input vertical synchronization signal, an input horizontal synchronization signal, a main clock, and a data enable signal.

The sensor control circuit T-IC may provide an electrical signal for driving the input sensor ISP to the input sensor ISP. The sensor control circuit T-IC may receive a control signal such as a clock signal from the main controller MC.

The electronic module EM may include various functional modules necessary for driving the electronic device ELD. For example, the electronic module EM may include a wireless communication module, an image input module, a sound input module, a sound output module, a memory, or an external interface module. The modules of the electronic module EM may be mounted on the main circuit board MCB or electrically connected to the main circuit board MCB through a separate flexible circuit board.

The power supply module PSM may be electrically connected to the electronic module EM. The power supply module PSM may supply power necessary for the overall operation of the electronic device ELD. For example, the power supply module PSM may include a typical battery device.

The window module WM and the housing EDC may be combined with each other to form the outer appearance of the electronic device ELD. The window module WM and the housing EDC are combined with each other to form an inner space therebetween to receive components of the electronic device ELD. The display module DM, the flexible circuit film FCB, the main circuit board MCB, the electronic module EM, and the power supply module PSM may be received in the inner space. A portion of the display module DM may be bent such that the flexible circuit film FCB and the main circuit board MCB face the rear surface of the display module DM and may be received in the housing EDC.

The housing EDC may include a material having more rigidity than the other components. For example, the housing EDC may include glass, plastic, or metal or may include a frame and/or plate including the combination thereof. The housing EDC may absorb an impact applied from the outside or prevent a foreign substance/moisture from being infiltrated from the outside to protect the display module DM accommodated in the housing EDC.

According to an embodiment of the present disclosure, the display panel DP in the electronic device ELD may be a component to generate an image. The display panel DP may be an emissive-type display panel. For example, the display panel DP may be an organic light emitting diode (OLED) display panel, an inorganic light emitting display panel, a quantum dot display panel, a micro-LED display panel, or a nano-LED display panel. The display panel DP may be referred to as a display layer.

Referring to FIG. 3, the display panel DP may include a base layer BS, a circuit layer DP-CL, a display element layer DP-ED, and an encapsulation layer TFE.

The base layer BS may provide a base surface for disposing the circuit layer DP-CL. The base layer BS may be a rigid substrate, or a flexible substrate allowing bending, folding, or rolling. The base layer BS may be a glass substrate, a metal substrate, or a polymer substrate. However, an embodiment is not necessarily limited thereto, and the base layer BS may be an inorganic film, an organic film, or a composite material layer.

The base layer BS may have a multi-layer structure. For example, the base layer BS may include a first synthetic resin layer, an intermediate layer in a multi-layer structure or a single-layer structure, and a second synthetic resin layer disposed on the intermediate layer. The intermediate layer may be referred to a base barrier layer. The intermediate layer may include a silicon oxide (SiOx) layer and an amorphous silicon (a-Si) layer disposed on the silicon oxide layer, but is not necessarily specifically limited thereto. For example, the intermediate layer may include a silicon oxide layer, a silicon nitride layer, a silicon oxynitride layer, and/or an amorphous silicon layer.

Each of the first and second synthetic resin layers may include polyimide-based resin. In addition, each of the first and second synthetic resin layers may include acrylate-based resin, methacrylate-based resin, polyisoprene-based resin, vinyl-based resin, epoxy-based resin, urethane-based resin, cellulose-based resin, siloxane-based resin, polyamide-based resin, and/or perylene-based resin. In the present specification, the wording “˜˜-based resin” may refer to that “˜˜-based resin” includes a functional group of “˜˜.”

The circuit layer DP-CL may be disposed on the base layer BS. The circuit layer DP-CL may include an insulating layer, a semiconductor pattern, an electrically conductive pattern, and a signal line. The insulating layer, the semiconductor layer, and the conductive layer are formed on the base layer BS through a coating scheme or a deposition scheme. The insulating layer, the semiconductor layer, and the conductive layer may be selectively patterned through a plurality of photolithography processes. Afterwards, the semiconductor pattern, the conductive pattern, and the signal line included in the circuit layer DP-CL may be formed. The circuit layer DP-CL may include a plurality of inorganic insulating layers and a plurality of organic insulating layers which are insulating layers.

The display element layer DP-ED may be disposed on the circuit layer DP-CL. The display element layer DP-ED may include a light emitting element. For example, the display element layer DP-ED may include an organic light emitting material, an inorganic light emitting material, an organic-inorganic light emitting material, a quantum dot, a quantum rod, a micro-LED, or a nano-LED. The light emitting elements of the display element layer DP-ED may be electrically connected to the driving elements of the circuit layer DP-CL to generate light and display an image in response to a signal provided by the driving elements.

The encapsulation layer TFE may be disposed on the display element layer DP-ED. The encapsulation layer TFE may protect the display element layer DP-ED from foreign objects such as moisture, oxygen, and dust particles. The encapsulation layer TFE may be disposed on the display element layer DP-ED. The encapsulation layer TFE may increase the optical efficiency of the display element layer DP-ED, or may include at least one thin film to protect the display element layer DP-ED.

The input sensor ISP may be disposed directly on the display panel DP. The input sensor ISP may sense the external input TC applied from the outside. The external input TC may be the input of the user US. The input of the user US may include various types of external inputs such as a part of a body of the user, a light, a heat, a pen, or a pressure. The input sensor ISP may sense the external input TC and provide an input signal including information on the external input TC, such that the display panel DP generates the image IM corresponding to the external input TC. The input sensor ISP may be driven in various ways such as a capacitive scheme, a resistive scheme, an infrared scheme, a sound wave scheme, or a pressure scheme, but is not necessarily limited to any one of the schemes. The following description will be made regarding that the input sensor ISP is driven through a capacitive scheme.

The input sensor ISP may be disposed on the display panel DP through a subsequent process. The input sensor ISP may be expressed as being disposed directly on the display panel DP. “The input sensor ISP may be disposed directly on the display panel DP” may refer to that a third component is not interposed between the input sensor ISP and the display panel DP. For example, an additional adhesive member may not be interposed between the input sensor ISP and the display panel DP.

The optical layer AF may be disposed on the input sensor ISP. The optical layer AF may be a reflection reducing layer to reduce the reflectance from the external light incident from the outside of the display module DM. The optical layer AF may be formed on the input sensor ISP through the subsequent process. For example, the optical layer AF may include a phase retarder and/or a polarizing film including a polarizer, multiple reflection layers to cancel reflection lights, or color filters arranged to correspond to a pixel arrangement of the display panel DP and a color of emitted light. For example, when the optical layer AF includes color filters, the color filter may be arranged based on the color of the light emitted from pixels included in the display panel DP. In addition, according to an embodiment of the present disclosure, the optical layer AF may be omitted.

FIG. 4 is a cross-sectional view illustrating a portion of a display module according to an embodiment of the present disclosure. FIG. 4 may illustrate a part taken along line II-II′ of FIG. 2. For example, FIG. 4 may be a cross-sectional view corresponding to a portion of the active region AA (see FIG. 2) of the display module DM.

According to an embodiment of the present disclosure, the display module DM may include the display panel DP and the input sensor ISP. The input sensor ISP may be referred to as a sensor layer, an input sensing layer, or an input sensing panel. The description of the display panel DP made with reference to FIGS. 2 and 3 will be identically applied to the following description on the display panel DP.

Referring to FIG. 4, the input sensor ISP includes a sensor base layer BL-IS, a sensor conductive layer MTL, and a sensor insulating layer ISL. The sensor base layer BL-IS may be disposed directly on the display panel DP.

According to an embodiment of the present disclosure, the sensor base layer BL-IS may include a buffer insulating layer LPD. In addition, the sensor base layer BL-IS may further include a base insulating layer ISL-B. For example, the input sensor ISP may be a stack structure including the buffer insulating layer LPD and the base insulating layer ISL-B, or a single layer including only the buffer insulating layer LPD.

The input sensor ISP may include the sensor base layer BL-IS, the sensor conductive layer MTL disposed on the sensor base layer BL-IS, and the sensor insulating layer ISL disposed on the sensor base layer BL-IS. For example, according to an embodiment of the present disclosure, the input sensor ISP may include the sensor base layer BL-IS, a first sensor conductive layer MTL1, a first sensor insulating layer ISL-C, a second sensor conductive layer MTL2, and a second sensor insulating layer ISL-T sequentially stacked on the display panel DP in the third direction DR3.

Each of the first sensor conductive layer MTL1 and the second sensor conductive layer MTL2 may have a single-layer structure or may have a multi-layer structure. The sensor conductive layer in the multi-layer structure may have a structure in which a transparent conductive layer and/or a metal layer are stacked in at least two layers. For example, the sensor conductive layer in the multi-layer structure may be a structure in which a transparent conductive layer and a metal layer are stacked, or may be a structure in which metal layers including mutually different metal are stacked.

A transparent conductive layer included in the first sensor conductive layer MTL1 and the second sensor conductive layer MTL2 may include indium tin oxide (ITO), indium zinc oxide (IZO), zinc oxide (ZnO), indium tin zinc oxide (ITZO), PEDOT, a metal nano-wire or graphene. The metal layer included in the first sensor conductive layer MTL1 and the second sensor conductive layer MTL2 may include molybdenum (Mo), silver (Ag), titanium (Ti), copper (Cu), aluminum (Mo), or an alloy thereof.

Metal having higher endurance and lower reflectance may be applied to an outer layer of the sensor conductive layer of the first sensor conductive layer MTL1 and the second sensor conductive layer MTL2 in the multi-layer structure, and metal having higher electrical conductivity may be applied to an inner layer of the sensor conductive layers. For example, the first sensor conductive layer MTL1 and the second sensor conductive layer MTL2 may have a triple structure including titanium/aluminum/titanium.

The first sensor conductive layer MTL1 and the second sensor conductive layer MTL2 may include sensing electrodes TE (see FIG. 6) of the input sensor ISP to be described below and may further include sensing wires TL (see FIG. 6).

The first sensor insulating layer ISL-C may be disposed on the first sensor conductive layer MTL1. The second sensor insulating layer ISL-T may be disposed on the second sensor conductive layer MTL2. Each of the first sensor insulating layer ISL-C and the second sensor insulating layer ISL-T may include an inorganic film. In addition, each of the first sensor insulating layer ISL-C and the second sensor insulating layer ISL-T may further include an organic film.

The first sensor insulating layer ISL-C and the second sensor insulating layer ISL-T may include silicon nitride (SiN_{X}) and/or silicon oxynitride (SiO_{X}N_{Y}). In addition, the first sensor insulating layer ISL-C and the second sensor insulating layer ISL-T may include silicon oxide (SiO_{X}). The first sensor insulating layer ISL-C and the second sensor insulating layer ISL-T may include aluminum oxide, titanium oxide, zirconium oxide, and/or hafnium oxide as inorganic films. The ‘X’ and ‘Y’ may be greater than ‘0’ respectively in the expressions of silicon nitride (SiN_{X}), silicon oxynitride (SiO_{X}N_{Y}) and silicon oxide (SiO_{X}).

When the first sensor insulating layer ISL-C and the second sensor insulating layer ISL-T include an organic film, the organic film may include an acrylic resin, a methacrylic resin, a polyisoprene, a vinyl resin, an epoxy resin, a urethane resin, a cellulose resin, a siloxane resin, a polyimide resin, a polyamide resin, and/or a perylene resin.

Although FIG. 4 illustrates that the input sensor ISP includes the first sensor conductive layer MTL1 and the second sensor conductive layer MTL2 stacked on each other, the embodiment is not necessarily limited thereto. For example, according to an embodiment of the present disclosure, the input sensor ISP may include one sensor conductive layer MTL disposed on the base insulating layer ISL-B. In this case, one of the first sensor insulating layer ISL-C and the second sensor insulating layer ISL-T may be omitted.

Although FIG. 4 illustrates that the first sensor conductive layer MTL1 and the second sensor conductive layer MTL2 are provided in the form of one layer overlapped with the entire portion of the display panel DP, the embodiment is not necessarily limited thereto. Each of the first sensor conductive layer MTL1 and the second sensor conductive layer MTL2 may be patterned.

According to an embodiment of the present disclosure, the buffer insulating layer LPD may have a higher content of oxygen when compared to insulating layers formed at the upper portion thereof. For example, the buffer insulating layer LPD may be an oxidized inorganic film.

According to an embodiment of the present disclosure, the buffer insulating layer LPD may include silicon (Si) and oxygen (O). The buffer insulating layer LPD may include SiO₂, and may include a Si element and an oxygen (O) element that do not form a compound in addition to the SiO₂.

In addition, according to an embodiment of the present disclosure, the buffer insulating layer LPD may include Si, O, and N. The buffer insulating layer LPD may include SiN_{X}, SiN_{X}O_{Y}, and/or SiO₂, and may include a Si element, an O element, and an N element in which a compound is not formed in addition to SiN_{X}, SiO_{X}N_{Y}, and SiO₂.

The atomic percent of oxygen (O) may be 67 at % or less based on the entire portion of the buffer insulating layer LPD. For example, the atomic percent of oxygen (O) in the buffer insulating layer LPD may be in the range from 2 at % to 67 at %. The buffer insulating layer LPD may include oxygen (O) having the atomic percent in the range from 2 at % to 67 at % to show strong bonding force with respect to an adjacent layer. In addition, an insulating layer on the buffer insulating layer LPD may show stronger bonding force with respect to a layer under the buffer insulating layer LPD.

The buffer insulating layer LPD may be formed through chemical vapor deposition (CVD). The buffer insulating layer LPD may be fabricated with a power that is lower than that in the fabrication process of an adjacent insulating layer formed through the CVD. The first power used in forming the buffer insulating layer LPD may be 35% or less of second power used in forming the base insulating layer ISL-B or the sensor insulating layer ISL when performing the fabricating process through the CVD. The buffer insulating layer LPD will be described in more detail thereafter.

FIG. 5 is a plan view of a display panel according to an embodiment of the present disclosure. Referring to FIG. 5, the display panel DP may include the base layer BS, pixels PX, signal lines SL1-SLm, DL1-DLn, EL1-ELm, CSL1, CSL2, and PL electrically connected to the pixels PX, a scan driver SDV, the data driver DIC, an emission driver EDV, and panel pads D-PD.

The base layer BS may provide a base surface on which elements and lines of the display panel DP are disposed. The base layer BS may include a display region DA and a non-display region NDA. The display region DA may be a region in which the pixels PX are disposed to display an image. The non-display region NDA may be a region for disposing elements and lines that are disposed adjacent to the display region DA to drive the pixels PX, and an image is not displayed in the non-display region NDA. The display region DA may correspond to the active region AA (FIG. 2) of the display module DM, and the non-display region NDA may correspond to the peripheral region NAA (FIG. 2) of the display module DM.

Each of the pixels PX may include a pixel driving circuit including transistors (e.g., a switching transistor, or a driving transistor) and a capacitor and a light emitting element electrically connected to the pixel driving circuit. The pixels PX may emit light corresponding to an electrical signal applied to the pixels PX.

Each of the scan driver SDV, the data driver DIC, and the emission driver EDV may be disposed in the non-display region NDA. However, the present disclosure is not necessarily limited thereto, and at least one of the scan driver SDV, the data driver DIC, and the emission driver EDV may be disposed in the display region DA. Accordingly, the area of the non-display region NDA may be reduced.

The signal lines SL1-SLm, EL1-ELm, DL1-DLn, CSL1, CSL2, and PL may include the scan lines SL1-SLm, the data lines DL1-DLn, the emission lines EL1-ELm, the first and second control lines CSL1 and CSL2, and the power line PL. In this case, “m” and “n” are positive integers. The pixels PX may be electrically connected to relevant scan lines, relevant data lines, and relevant emission lines of the scan lines SL1-SLm, the data lines DL1-DLn, and the emission lines EL1-ELm. Many more types of signal lines may be provided on the display panel DP depending on the configuration of the pixel driving circuit of the pixels PX.

The scan lines SL1-SLm may be electrically connected to the scan driver SDV while extending in the first direction DR1. The data lines DL1-DLn may be electrically connected to the data driver DIC while extending in the second direction DR2. The emission lines EL1-ELm may be electrically connected to the emission driver EDV while extending in the first direction DR1.

The power line PL may include a part extending in the first direction DR1 and a part extending in the second direction DR2. The part, which extends in the first direction DR1, of the power line PL may be disposed in a non-display region NDA. The part, which extends in the second direction DR2, of the power line PL may be electrically connected to the pixels PX and the part, which extends in the first direction DR1, of the power line PL. The part, which extends in the second direction DR2, of the power line PL, may be disposed at a layer different from a layer of the part, which extends in the first direction DR1, of the power line PL and may be connected to the part, which extends in the first direction DR1, of the power line PL through a contact hole. For example, the part, which extends in the second direction DR2, of the power line PL, may have the form integrated with the part, which extends in the first direction DR1, of the power line PL at the same layer.

The first control line CSL1 may be electrically connected to the scan driver SDV. The second control line CSL2 may be electrically connected to the emission driver EDV.

The panel pads D-PD may be disposed adjacent to a lower end of the non-display region NDA. The panel pads D-PD may be disposed closer to the lower portion of the display panel DP rather than the data driver DIC. The panel pads D-PD may be spaced apart from each other in the first direction DR1. The panel pads D-PD may be parts to which a circuit board for providing signal for controlling the operations of the scan driver SDV, the data driver DIC, and the emission driver EDV of the display panel DP is electrically connected.

The panel pads D-PD may be defined as display pads electrically connected to the pixels PX. The panel pads D-PD may be connected to relevant signal lines of the signal lines SL1-SLm, EL1-ELm, DL1-DLn, CSL1, CSL2, and PL. For example, the power line PL, the first and second control lines CSL1 and CSL2, the data lines DL1-DLn may be connected to relevant panel pads D-PD. The data lines DL1-DLn may be connected to the relevant panel pad D-PD through the data driver DIC.

The scan driver SDV may generate scan signals in response to a scan control signal. The scan signals may be applied to the pixels PX through the scan lines SL1-SLm. The data driver DIC may generate data voltages corresponding to the image signals, in response to the data control signal. The data voltages may be applied to the pixels PX through the data lines DL1-DLn. The emission driver EDV may generate emission signals in response to an emission control signal. The emission signals may be applied to the pixels PX through the emission lines EL1-ELm.

The pixels PX may receive data voltages in response to the scan signals. The pixels PX may display the image, as the pixels PX emit light having brightness corresponding to data voltages, in response to the emission signals. The time to emit light by the pixels PX may be controlled through the light emitting signals. Accordingly, the display panel DP may generate an image onto the display region DA through the pixels PX.

FIG. 6 is a plan view of the input sensor ISP according to an embodiment of the present disclosure. Referring to FIG. 6, the input sensor ISP may include a sensing region AA-S and a non-sensing region NAA-S adjacent to the sensing region AA-S. The sensing region AA-S may correspond to the active region AA (see FIG. 2) of the display module. The sensing region AA-S may be a region for disposing the sensing electrodes TE of the input sensor ISP to sense the external input TC (see FIG. 1). The non-sensing region NAA-S may correspond to the peripheral region NAA (see FIG. 2) of the display module. The non-sensing region NAA-S may be a region for disposing an element or lines for driving the sensing electrodes TE disposed in the sensing region AA-S.

The input sensor ISP may include the sensing electrodes TE, sensing lines TL, and sensing pads T-PD disposed on the sensor base layer BL-IS.

The sensing electrodes TE may include first sensing electrodes TE1 and second sensing electrodes TE2 electrically insulated from each other while crossing each other, when viewed on a plan view. The input sensor ISP may acquire information on an external input through the variation in mutual capacitance between the first sensing electrodes TE1 and the second sensing electrodes TE2.

The first sensing electrodes TE1 may extend in the first direction DR1, and may be arranged in the second direction DR2. The first sensing electrodes TE1 may be provided in multiple rows arranged in the second direction DR2. Although FIG. 6 illustrates 10 first sensing electrodes TE1 arranged in the second direction DR2, the number of first sensing electrodes TE1 included in the input sensor ISP is not necessarily limited thereto.

The second sensing electrodes TE2 may extend in the second direction DR2, and may be arranged in the first direction DR1. The second sensing electrodes TE2 may be provided in multiple columns arranged in the first direction DR1. Although FIG. 6 illustrates 8 second sensing electrodes TE2 arranged in the first direction DR1, the number of second sensing electrodes TE2 included in the input sensor ISP is not necessarily limited thereto.

Each of the first sensing electrodes TE1 may include first sensing patterns SP1 and first connection patterns BP1. The first sensing patterns SP1 may be arranged in the first direction DR1. The first connection patterns BP1 may connect the first sensing patterns SP1, which are adjacent to each other in the first direction DR1, to each other. The first connection patterns BP1 may be disposed at the same layer as that of the first sensing patterns SP1. For example, the first connection patterns BP1 may have the form integrated with the first sensing patterns SP1 while extending from the first sensing patterns SP1. The first sensing patterns SP1 and the first connection patterns BP1 may be patterns patterned and formed from the same conductive layer through the same process. However, an embodiment is not necessarily limited thereto as long as the first connection patterns BP1 electrically connect the first sensing patterns SP1, which are adjacent to each other in the first direction DR1, to each other.

Each of the second sensing electrodes TE2 may include second sensing patterns SP2 and second connection patterns BP2. The second sensing patterns SP2 may be arranged in the second direction DR2. The second connection patterns BP2 may connect the second sensing patterns SP2, which are adjacent to each other in the second direction DR2, to each other. For example, the second connection patterns BP2 may be formed at a layer different from a layer of the second sensing patterns SP2 and may be connected to the relevant second sensing patterns SP2 through the contact hole. The second sensing patterns SP2 spaced apart from each other in the second direction DR2 may be electrically connected through the second connection patterns BP2. The second connection patterns BP2 disposed at a layer different from a layer of the second sensing patterns SP2 to connect the second sensing patterns SP2 to each other may be defined as bridge patterns.

According to an embodiment of the present disclosure, the first sensing patterns SP1, the first connection patterns BP1, and the second sensing patterns SP2 may be disposed on the same layer. The second connection patterns BP2 may be disposed at a layer different from a layer of the second sensing patterns SP2. For example, the first sensing patterns SP1, the first connection patterns BP1, and the second sensing patterns SP2 may be included in the second sensor conductive layer MTL2 (See FIG. 4), and the second connection patterns BP2 may be included in the first sensor conductive layer MTL1 (see FIG. 4). However, the embodiment is not necessarily limited thereto. For example, the first sensing patterns SP1, the first connection patterns BP1, and the second sensing patterns SP2 may be included in the first sensor conductive layer MTL1 (see FIG. 4), and the second connection patterns BP2 may be included in the second sensor conductive layer MTL2 (see FIG. 4). For example, according to an embodiment of the present disclosure, the first sensing patterns SP1, the second sensing patterns SP2, and the second connection patterns BP2 may be disposed on the same layer, and the first connection patterns BP1 may be disposed on a layer different from a layer of the first sensing patterns SP1.

The sensing lines TL may include first sensing lines TL1 and second sensing lines TL2. The first sensing lines TL1 may be connected to the first sensing electrodes TE1, respectively. The first sensing lines TL1 may be connected to relevant first sensing electrode TE1 of the first sensing electrodes TE1 provided in the multiple rows. The second sensing lines TL2 may be connected to the second sensing electrodes TE2, respectively. The second sensing lines TL2 may be connected to the relevant second sensing electrode TE2 of the second sensing electrodes TE2 provided in multiple columns.

The second sensing lines TL2 may be connected to lower portions of the second sensing electrodes TE2 adjacent to the sensing pads T-PD. The second sensing lines TL2 may extend from a lower portion of the relevant second sensing electrode TE2 and may be connected to the sensing pads T-PD on the non-sensing region NAA-S.

As illustrated in FIG. 6, the first sensing lines TL1 may be connected to a left portion or a right portion of the first sensing electrodes TE1. For example, each of the first sensing lines TL1, which are connected to the first sensing electrodes TE1 in the odd-numbered row, of the first sensing lines TL1 may be connected to a left portion of the relevant first sensing electrode TE1 of the first sensing electrodes TE1 provided in the odd-numbered row. For example, each of the first sensing lines TL1, which are connected to the first sensing electrodes TE1 in an even-numbered row, of the first sensing lines TL1 may be connected to a right portion of the relevant first sensing electrode TE1 of the first sensing electrodes TE1 provided in the even-numbered row. The first sensing lines TL1 may extend in the second direction DR2 from a left portion or a right portion of the relevant first sensing electrode TE1 and may be connected to the sensing pads T-PD on the non-sensing region NAA-S.

The sensing pads T-PD may be disposed in the non-sensing region NAA-S. The sensing pads T-PD may be adjacent to a lower portion of the sensor base layer BL-IS. The sensing pads T-PD may be electrically connected to the sensing lines TL. The sensing pads T-PD may be spaced apart from the sensing pads T-PD and electrically connected to the sensing lines TL. The sensing pads T-PD may be a part electrically connected to the circuit board providing a driving signal. A signal can be applied to the sensing electrodes TE through the sensing pads T-PD and the sensing lines TL. And the circuit board may receive a signal from the sensing electrodes TE through sensing pads T-PD and the sensing lines TL.

According to an embodiment of the present disclosure, driving signals for driving the first sensing electrodes TE1 and the second sensing electrodes TE2 may be applied to the first sensing electrodes TE1 and the second sensing electrodes TE2 through the second sensing lines TL2. The signal including information sensed by the first sensing electrodes TE1 and the second sensing electrodes TE2 may be output through the first sensing lines TL1. However, the embodiment is not necessarily limited thereto.

The sensing pads T-PD may be formed integrally with the sensing lines TL corresponding to the sensing pads T-PD. The sensing pads T-PD may be separated from the sensing lines TL, and one end portion of the sensing lines TL may correspond to a sensing pad part connected to a driving chip in the circuit board.

The sensing pads T-PD and the sensing lines TL may be formed based on the sensing conductive layer MTL (see FIG. 4) of the input sensor. For example, the sensing pads T-PD and the sensing lines TL may be formed through the same process as that of the first sensor conductive layer MTL1. However, the embodiment is not necessarily limited thereto. Depending on the locations of the sensing electrodes TE, the sensing pads T-PD and the sensing lines TL may be formed through the same process as that of the second sensor conductive layer MTL2, or some of the sensing pads T-PD and the sensing lines TL may be formed through the same process as that of the first sensor conductive layer MTL1 and some of the sensing pads T-PD and the sensing lines TL may be formed through the same process as that of the second sensor conductive layer MTL2.

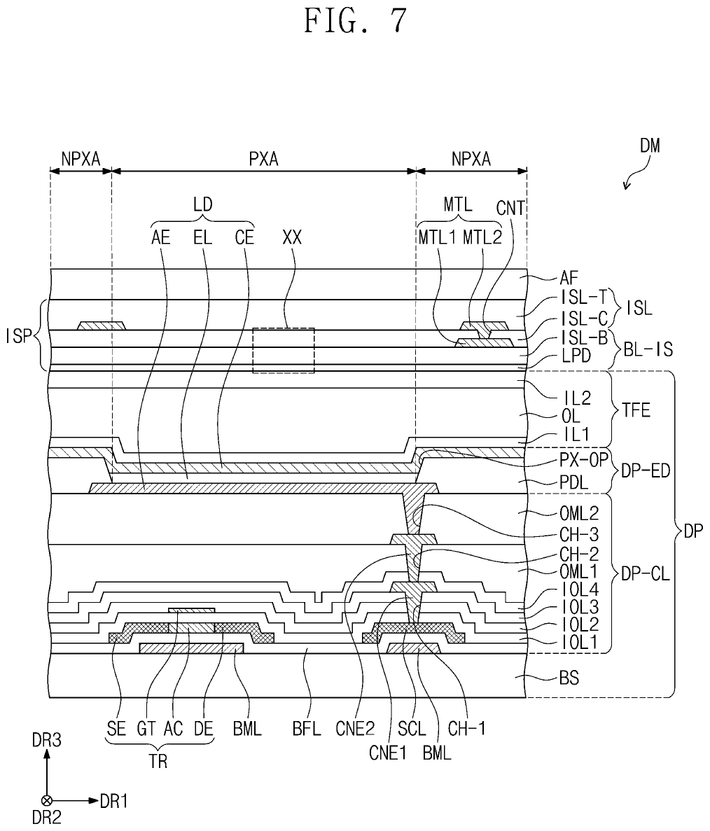

FIG. 7 is a cross-sectional view of a portion of a display module according to an embodiment of the present disclosure. FIG. 7 is a cross-sectional view of the display module DM in a part including any one pixel PX (see FIG. 5) illustrated in FIG. 5. The display module DM includes the display panel DP and the input sensor ISP, and the display panel DP includes the base layer BS, the circuit layer DP-CL, the display element layer DP-ED, and the encapsulation layer TFE. Any one pixel PX (see FIG. 5) may have an equivalent circuit including a plurality of transistors, one capacitor, and a light emitting element, and the equivalent circuit of the pixel may be modified in various forms. One transistor TR and one light emitting element LD included in the pixel PX (see FIG. 5) are illustrated in FIG. 7 by way of example.

According to an embodiment of the present disclosure, the display panel DP may include a plurality of insulating layers, a transistor, an electrically conductive pattern, and a signal line.

A plurality of inorganic films, a plurality of organic films, a semiconductor layer, and an electrically conductive layer may be formed through a coating process, and a depositing process. Thereafter, the inorganic films, the organic films, the semiconductor layer, and the conductive layer may be selectively patterned through a photolithography scheme. In such a manner, the circuit layer DP-CL including the plurality of insulating layers formed from the inorganic films and the organic films, the transistor including the semiconductor pattern formed from the semiconductor layer, and an electrically conductive pattern and the signal line formed from the conductive layer may be formed.

Thereafter, the display element layer DP-ED including the light emitting element LD including the conductive pattern may be formed on the circuit layer DP-CL, and the encapsulation layer TFE may cover the display element layer DP-ED.

Referring to FIG. 7, the circuit layer DP-CL may include a shielding electrode BML, a buffer layer BFL, a plurality of insulating layers IOL1, IOL2, IOL3, and IOL4 including an inorganic film, a plurality of insulating layers OML1, OML2 including an organic film, a transistor TR, connection electrodes CNE1 and CNE2, and a signal line SCL.

The shielding electrode BML may be disposed on the base layer BS. The shielding electrode BML may be overlapped with the transistor TR. In addition, according to an embodiment of the present disclosure, the shielding electrode BML may be disposed under the signal line SCL. The shielding electrode BML may protect a semiconductor pattern or an electrically conductive pattern, such as the transistor TR and the signal line SCL by blocking light incident on the transistor TR or the signal line SCL from the lower portion of the display panel DP. The shielding electrode BML may include an electrically conductive material. According to an embodiment of the present disclosure, the shielding electrode BML may be connected to the power line PL (see FIG. 5) to receive a voltage. When a voltage is applied to the shielding electrode BML, a threshold voltage of the transistor TR disposed on the shielding electrode BML may be maintained. The present disclosure is not necessarily limited thereto, and the shielding electrode BML may be a floating electrode. According to an embodiment of the present disclosure, the shielding electrode BML may be omitted.

The buffer layer BFL may be disposed on the base layer BS to cover the shielding electrode BML. The buffer layer BFL may increase a coupling force between a semiconductor pattern or an electrically conductive pattern disposed on the buffer layer BFL, and the base layer BS. In addition, the buffer layer BFL may prevent the diffusion of metal atoms or impurities from the base layer BS into the semiconductor pattern or the conductive pattern.

The buffer layer BFL may be an inorganic film. The buffer layer BFL may include silicon oxide, silicon nitride, and/or silicon oxynitride. For example, the buffer layer BFL may include a structure in which a silicon oxide layer and a silicon nitride layer are alternately stacked.

The transistor TR may include a source SE, a channel AC, a drain DE, and a gate GT. The source SE, the channel AC, and the drain DE of the transistor TR may be formed from a semiconductor pattern. The source SE and the drain DE may extend in opposite directions from the channel AC, when viewed in a cross-sectional view. In addition, FIG. 7 illustrates a portion of the signal line SCL formed from the semiconductor pattern. The signal line SCL may be connected to the drain DE of the transistor TR, when viewed in a plan view.

The semiconductor pattern of the transistor TR may include polysilicon, amorphous silicon, or metal oxide, and the present disclosure is not necessarily limited to any one material as long as the material has a semiconductor property.

The semiconductor pattern may include a plurality of regions divided depending on the strength of the conductivity. Among semiconductor patterns, a region doped with dopants or a region in which a metal oxide is reduced shows greater electrical conductivity. The region may substantially serve as a source and drain electrode of the transistor TR. The region showing a higher conductivity in the semiconductor pattern may correspond to the source region SE and the drain region DE of the transistor TR. A region, which is not doped or doped at a lightly concentration, or a region, which shows a lower conductivity, as the metal oxide is not reduced, may correspond to the channel AC (or active) of the transistor TR.

The first insulating layer IOL1 may cover a semiconductor pattern of the transistor TR and may be disposed on the buffer layer BFL. The gate GT of the transistor TR may be disposed on the first insulating layer IOL1. The gate GT may be overlapped with the channel AC of the transistor TR. According to an embodiment of the present disclosure, the gate GT may function as a mask in a process of doping a semiconductor pattern of the transistor TR.

The gate GT may include, but is not necessarily limited to including, titanium (Ti), silver (Ag), an alloy containing silver (Ag), molybdenum (Mo), an alloy containing molybdenum (Mo), aluminum (Al), an alloy containing aluminum (Al), an aluminum nitride (AlN), tungsten (W), a tungsten nitride (WN), copper (Cu), indium tin oxide (ITO), and indium zinc oxide (IZO).

The first insulating layer IOL1 may include an inorganic film. The first insulating layer IOL1 may be referred to as a first inorganic film. For example, the first insulating layer IOL1 may be an inorganic film including aluminum oxide, titanium oxide, silicon oxide, silicon nitride, silicon oxynitride, zirconium oxide, and/or hafnium oxide. The first insulating layer IOL1 may have a single layer structure or a multi-layer structure. The first insulating layer IOL1 may have a structure in which a plurality of inorganic films are stacked. When the first insulating layer IOL1 has a structure in which a plurality of layers are stacked, the first insulating layer IOL1 may further include a buffer inorganic film disposed directly under the inorganic film and having a higher content of oxygen (O), when compared to an adjacent inorganic film. The buffer inorganic film may have a physical property similar to that of the buffer insulating layer of the input sensor described above.

In addition, according to an embodiment of the present disclosure, the first insulating layer IOL1 may further include an organic film in addition to the inorganic film. When the first insulating layer IOL1 has the structure in which the inorganic film and the organic film are stacked, the first insulating layer IOL1 may further include a buffer inorganic film interposed between the inorganic film and the organic film adjacent to each other. In this case, the buffer inorganic film may have a physical property similar to that of the buffer insulating layer of the input sensor described above. For example, the buffer inorganic film may include oxygen (O) and carbon (C) provided at a higher content, when compared to the adjacent inorganic film.

The multi-layer structure described in relation to the first insulating layer IOL1 may be applied to the second insulating layer to the fourth insulating layer IOL2, IOL3, and IOL4 described thereafter. Accordingly, the stack structure of the insulating layer in the multi-layer structure and the configuration of the buffer inorganic film in the multi-layer structure may be identically applied even to the second insulating layer to the fourth insulating layer IOL2, IOL3, and IOL4.

The second insulating layer IOL2 may be disposed on the first insulating layer IOL1 and may cover the gate GT. The second insulating layer IOL2 may be commonly provided in the pixels. The second insulating layer IOL2 may include the inorganic film. The second insulating layer IOL2 may be referred to as the second inorganic film. For example, the second insulating layer IOL2 may include silicon oxide, silicon nitride, and/or silicon oxynitride. The second insulating layer IOL2 may be an inorganic film and/or an organic film, and may have a single-layer structure or a multi-layer structure. According to an embodiment of the present disclosure, the second insulating layer IOL2 may have a multi-layer structure including a silicon oxide layer and a silicon nitride layer.

The third insulating layer IOL3 may be disposed on the second insulating layer IOL2. The third insulating layer IOL3 may include the inorganic film. The third insulating layer IOL3 may be referred to as the third inorganic film. The third insulating layer IOL3 may have a single layer structure or a multi-layer structure. According to an embodiment of the present disclosure, the third insulating layer IOL3 may have a multi-layer structure including a silicon oxide layer and a silicon nitride layer.

The first connection electrode CNE1 may be disposed on the third insulating layer IOL3. The first connection electrode CNE1 may be connected to the signal line SCL through a first contact hole CH-1 formed through the first insulating layer IOL1, the second insulating layer IOL2, and the third insulating layer IOL3.

The fourth insulating layer IOL4 may be disposed on the third insulating layer IOL3. The fourth insulating layer IOL4 may include an inorganic film, and may be referred to as a fourth inorganic film. The fourth insulating layer IOL4 may be a silicon oxide layer having a single-layer structure.

The fifth insulating layer OML1 may be disposed on the fourth insulating layer IOL4. The fifth insulating layer OML1 may include the organic film. The fifth insulating layer OML1 may be referred to as the first organic film. For example, the organic film may include acrylic resin, methacrylic resin, polyisoprene, vinyl resin, epoxy resin, urethane resin, cellulose resin, siloxane resin, polyamide resin, and/or a perylene resin.

The second connection electrode CNE2 may be disposed on the fifth insulating layer OML1. The second connection electrode CNE2 may be connected to the first connection electrode CNE1 through a second contact hole CH-2 formed through the fourth insulating layer IOL4, and the fifth insulating layer OML1.

A sixth insulating layer OML2 may be disposed on the fifth insulating layer OML1 and may cover the second connection electrode CNE2. The sixth insulating layer OML2 may include the organic film. The sixth insulating layer OML2 may be referred to as the second organic film. For example, the second organic film may include acrylic resin, methacrylic resin, polyisoprene, vinyl resin, epoxy resin, urethane resin, cellulose resin, siloxane resin, polyamide resin, and/or a perylene resin.

The circuit layer may further include a plurality of transistors, and may further include signal lines electrically connected to the plurality of transistors. The signal lines may extend and may be connected to the panel pads D-PD of the non-display region NDA (see FIG. 5). In addition, the signal lines may extend and may be connected to the sensing pads T-PD of the non-sensing region NAA-S (see FIG. 6).

The display element layer DP-ED may be disposed on the circuit layer DP-CL. The display element layer DP-ED may include a pixel defining layer PDL and the light emitting element LD. The light emitting element LD may include a first electrode AE, a light emitting layer EL, and a second electrode CE.

The first electrode AE may be disposed on the sixth insulating layer OML2. The first electrode AE may be connected to the second connection electrode CNE2 through a third contact hole CH-3 formed through the sixth insulating layer OML2. The first electrode AE may be electrically connected to the drain DE of the transistor TR through the first and second connection electrodes CNE1 and CNE2.

The first electrode AE may be referred to as a pixel electrode. The first electrode AE may include a metal material, a metal alloy, or an electrically conductive compound. The first electrode AE may be an anode or a cathode. The first electrode AE may be a transmission electrode, a semi-transmission electrode, or a reflective electrode. When the first electrode AE is a transmission electrode, the first electrode AE may include a transparent metal oxide, for example, indium tin oxide (ITO), indium zinc oxide (IZO), zinc oxide (ZnO), and indium tin oxide (ITZO). When the first electrode AE is a semi-transmission electrode or a reflective electrode, the first electrode AE may include a mixture of Ag, Mg, Cu, Al, Pt, Pd, Au, Ni, Nd, Ir, Cr, Li, Ca, LiF/Ca, LiF/Al, Mo, Ti, W or the compound thereof or the mixture thereof (for example, the mixture of Ag and Mg). For example, the first electrode AE may have a multi-layer structure including a reflective layer or a semi-transmission layer including the above materials, and a transmission conductive layer including indium tin oxide (ITO), indium zinc oxide (IZO), zinc oxide (ZnO), and indium tin zinc oxide (ITZO). For example, the first electrode AE may include a three-layer structure of ITO/Ag/ITO, but the present disclosure is not necessarily limited thereto. In addition, an embodiment is not necessarily limited thereto. The first electrode AE may include the above-described metal material, the combination of at least two types of metal materials selected from the above-described metal materials, or an oxide of the above-described metal materials.

The pixel defining layer PDL may be disposed on the sixth insulating layer OML2. According to an embodiment of the present disclosure, the pixel defining layer PDL may be formed of a polymer resin. For example, the pixel defining layer PDL may be formed by including a polyacrylate-based resin or a polyimide-based resin. In addition, the pixel defining layer PDL may further include an inorganic material in addition to a polymer resin. The pixel defining layer PDL may be formed by including a light absorbing material, or may be formed by including a black pigment or a black dye. The pixel defining layer PDL formed by including a black pigment or a black dye may implement a black pixel defining layer. When the pixel defining layer PDL is formed, carbon black may be used as a black pigment or a black dye, but the embodiment is not necessarily limited thereto.

In addition, the pixel defining layer PDL may include an inorganic material. For example, the pixel defining layer PDL may include silicon nitride, silicon oxide, or silicon oxynitride.

A pixel opening PX-OP exposing a portion of the first electrode AE may be defined in the pixel defining layer PDL. According to an embodiment of the present disclosure, light emitting regions PXA may be divided by the pixel defining layer PDL in the display module DM. The display module DM may include the light emitting regions PXA and a non-light emitting region NPXA. The non-light emitting region NPXA may be overlapped with the pixel defining layer PDL. A portion, which corresponds to the first electrode AE exposed, of the pixel opening PX-OP may be defined as the light emitting region PXA.

The light emitting layer EL in the light emitting element LD may be disposed on the first electrode AE. According to an embodiment of the present disclosure, the light emitting layer EL may emit light having at least one color of blue, red, and green. According to an embodiment of the present disclosure, the light emitting layer EL may provide blue light in the entire portion of the display region DA (see FIG. 5).

The second electrode CE may be disposed on the light emitting layer EL. The second electrode CE may be integrally and commonly disposed in the plurality of pixels PX (see FIG. 5). The second electrode CE may be referred to as a common electrode. The second electrode CE may be a cathode or an anode. For example, when the first electrode AE is an anode, the second electrode CE may be a cathode. When the first electrode AE is a cathode, the second electrode CE may be an anode.

The second electrode CE may be a transmission electrode, a semi-transmission electrode, or a reflective electrode. When the second electrode CE is a transmission electrode, the second electrode CE may include a transparent metal oxide, for example, indium tin oxide (ITO), indium zinc oxide (IZO), zinc oxide (ZnO), and indium tin oxide (ITZO). When the second electrode CE is a semi-transmission electrode or a reflective electrode, the second electrode CE may include a mixture of Ag, Mg, Cu, Al, Pt, Pd, Au, Ni, Nd, Ir, Cr, Li, Ca, LiF/Ca, LiF/Al, Mo, Ti, W or the compound thereof or the mixture thereof (for example, the mixture of Ag and Mg).

A hole control layer may be disposed between the first electrode AE and the light emitting layer EL. The hole control layer may include a hole transport layer and may further include a hole injection layer. An electron control layer may be interposed between the light emitting layer EL and the second electrode CE. The electron control layer may include an electron transport layer, and may further include an electron injection layer. The hole control layer and the electron control layer may be formed, in common, in a plurality of pixels PX (see FIG. 5), for example, by using an open mask.

The encapsulation layer TFE may be disposed on the display element layer DP-ED. The encapsulation layer TFE may include a first inorganic film IL1, an organic film OL, and a second inorganic film IL2 sequentially stacked on each other. However, the layers constituting the encapsulation layer TFE is not necessarily limited thereto.

The inorganic films IL1 and IL2 may protect the display element layer DP-ED from moisture and oxygen, and the organic film OL may protect the display element layer DP-ED from a foreign substance such as dust particles. The inorganic films IL1 and IL2 may include silicon nitride, silicon oxynitride, titanium oxide, and/or aluminum oxide. Zirconium oxide, or hafnium oxide. The organic film OL may include an acrylic organic material. However, the types of materials constituting the inorganic films IL1 and IL2 and the organic film OL are not necessarily limited thereto.

The input sensor ISP may be disposed on the encapsulation layer TFE. As described with reference to FIG. 4, according to an embodiment of the present disclosure, the input sensor ISP may include the sensor base layer BL-IS, the sensor conductive layers MTL1 and MTL2, and the sensor insulating layers ISL-C and ISL-T.

FIG. 7 illustrates a multi-layer structure including the first sensor conductive layer MTL1 and the second sensor conductive layer MTL2. The second sensor conductive layer MTL2 may be connected to the first sensor conductive layer MTL1 through a contact hole CNT. However, the embodiment is not necessarily limited thereto. The input sensor ISP may include a sensor conductive layer in a single layer. In this case, one of the sensor insulating layers ISL-C and ISL-T may be omitted.

According to an embodiment of the present disclosure, the sensor base layer BL-IS may include the base insulating layer ISL-B and the buffer insulating layer LPD. The buffer insulating layer LPD may be disposed directly on a bottom surface of the base insulating layer ISL-B. The buffer insulating layer LPD may be disposed directly on the encapsulation layer TFE. For example, the buffer insulating layer LPD may be disposed directly on the second inorganic film IL2 of the encapsulation layer TFE.

According to an embodiment of the present disclosure, the buffer insulating layer LPD may be overlapped with the encapsulation layer TFE in the entire portion of the active region AA (see FIG. 2) of the display module DM. For example, according to an embodiment of the present disclosure, the buffer insulating layer LPD, which serves as a common layer, may be provided in the entire portion of the active region AA (see FIG. 2).

Referring to FIG. 7, according to an embodiment of the present disclosure, the display module DM may include the optical layer AF. According to an embodiment of the present disclosure, the optical layer AF may be disposed directly on the sensor insulating layer ISL-T. However, the embodiment is not necessarily limited thereto. For example, an adhesive layer may be further interposed between the optical layer AF and the input sensor ISP.

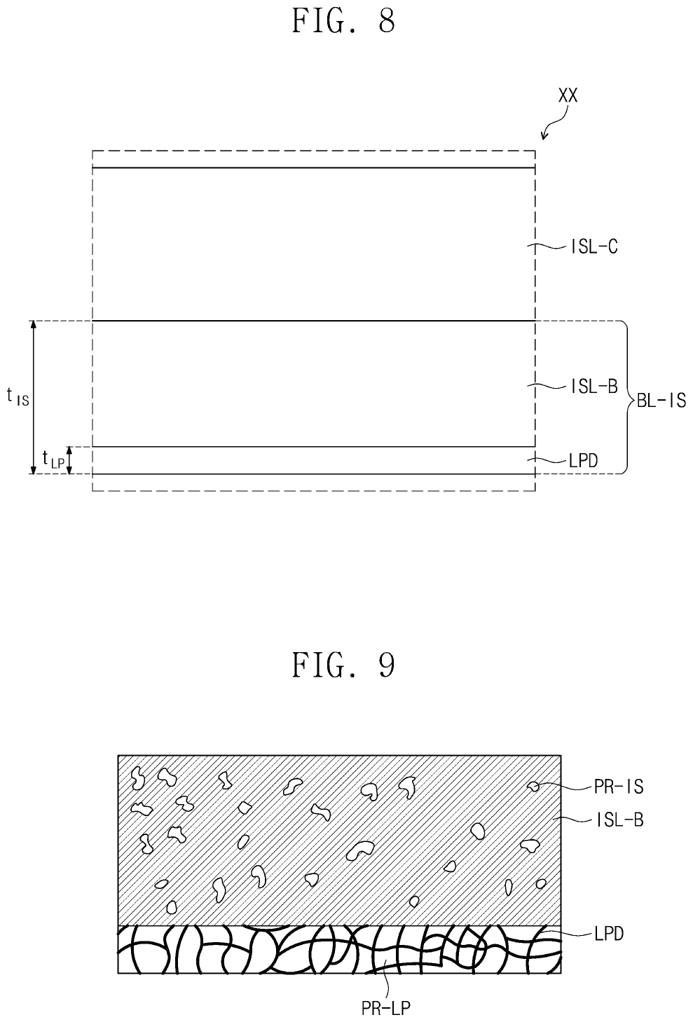

FIG. 8 is a cross-sectional view illustrating a part of an input sensor. FIG. 8 illustrates region ‘XX’ of FIG. 7. FIG. 9 is a schematic view illustrating a part of the input sensor in more detail.

FIG. 8 illustrates the stack structure of the sensor base layer BL-IS and the first sensor insulating layer ISL-C, which is a part of the input sensor illustrated in FIG. 7. FIG. 8 is a view without a sensor conductive layer.

According to an embodiment of the present disclosure, the base insulating layer ISL-B may be formed through a CVD scheme. Even the buffer insulating layer LPD may be formed through the CVD. The buffer insulating layer LPD may be formed through the CVD under a condition the same as a condition for forming the base insulating layer ISL-B other than a power condition. The buffer insulating layer LPD may be treated by using the same source gas and plasma as those of the base insulating layer ISL-B. Regarding power, the buffer insulating layer LPD may be formed under the condition of power corresponding to 35% or less of the power of the base insulating layer ISL-B.

The buffer insulating layer LPD formed under the condition of lower power may have higher porosity when compared to the base insulating layer ISL-B. The porosity may be defined as a ratio occupied by the pores in unit volume. In this specification, an empty space, which is not filled with a material including the compounds of the materials, of a layer including the inorganic material, may be referred as a pore.

FIG. 9 is a cross-sectional view illustrating the comparison in porosity. Referring to FIG. 9, the ratio of a first pore PR-LP included in the buffer insulating layer LPD may be greater than the ratio of a second pore PR-IS included in the base insulating layer ISL-B. In addition, the area occupied by the first pore PR-LP in a unit area may be greater than an area occupied by the second pore PR-IS when viewed in a cross-sectional view.

The buffer insulating layer LPD having the higher porosity may have the pore PR-LP including the organic foreign substances. For example, the buffer insulating layer LPD may include oxygen atoms which do not form the inorganic compound and carbon atoms which do not form the organic compound. The oxygen atoms, the carbon atoms, or the assembly of the oxygen atoms and the carbon atoms may be positioned in the pore PR-LP. For example, oxygen (O₂) gas, and an organic oxide (an organic substance including carbon and oxygen) may be positioned in the pore PR-LP. However, the embodiment is not necessarily limited thereto. Various types of impurities or gas may be trapped in the pore PR-LP.

As described above, the buffer insulating layer LPD having the higher porosity is provided to prevent the impurities, which are produced at a lower portion of the input sensor ISP (see FIG. 7), from being transferred to the upper portion of the buffer insulating layer LPD. Accordingly, the electronic device may have the high reliability characteristic. In addition, gas (outgas) to be produced under a higher-temperature environment or a high-temperature/higher-humidity environment may be sufficiently trapped in the buffer insulating layer LPD. Accordingly, the reliability of the electronic device may be increased under a severe use condition.

The buffer insulating layer LPD may be thinner when compared to the adjacent base insulating layer ISL-B. The total thickness t_{IS} of the sensor base layer BL-IS may be greater than or equal to 1000 Å and less than or equal to 3000 Å. The thickness t_{LP} of the buffer insulating layer LPD in the sensor base layer BL-IS may be 10% or more of the total thickness t_{IS} of the sensor base layer BL-IS. The thickness t_{LP} of the buffer insulating layer LPD may be greater than or equal to 150 Å. According to an embodiment of the present disclosure, the thickness t_{LP} of the buffer insulating layer LPD may be greater than or equal to 1000 Å. For example, according to an embodiment of the present disclosure, the thickness t_{LP} of the buffer insulating layer LPD may be greater than or equal to 150 Å and less than or equal to 3000 Å.

The buffer insulating layer LPD may be provided with the thickness ranging from 150 Å to 3000 Å to sufficiently trap gas (outgas) produced from the lower portion of the buffer insulating layer LPD to protect components of the input sensor ISP on the buffer insulating layer LPD. In addition, the buffer insulating layer LPD may be provided with the thickness ranging from 150 Å to 3000 Å such that an adjacent base insulating layer ISL-B maintains sufficient bonding force with a lower layer through the buffer insulating layer LPD.

According to an embodiment of the present disclosure, the base insulating layer ISL-B may be a layer including silicon nitride (SiNₓ). The base insulating layer ISL-B may further include oxygen (O) atoms in addition to a silicon nitride compound.

The buffer insulating layer LPD disposed directly on the bottom surface of the base insulating layer ISL-B may be a layer including Si, N, and O atoms. For example, the buffer insulating layer LPD may include silicon nitride (SiN_{X}), silicon oxynitride (SiO_{X}N_{Y}), and/or silicon oxide (SiO_{X}), and may include oxygen atoms which do not form the composition of the above-described compounds. In addition, the buffer insulating layer LPD may further include atoms of Si or N which does not form the composition of the inorganic compound described above.

The oxygen (O) atom percent in the buffer insulating layer LPD may be two times to 100 times than the oxygen (O) atom percent in the base insulating layer ISL-B. For example, the base insulating layer ISL-B may contain a small amount of oxygen atoms, and the buffer insulating layer LPD may contain 5 times or more oxygen atoms than the base insulating layer ISL-B.

According to an embodiment of the present disclosure, each of the base insulating layer ISL-B and the buffer insulating layer LPD may further include a carbon (C) atom. The percent of carbon (C) atoms in the buffer insulating layer LPD may be 2 times to 100 times the percent of carbon (C) atoms in the base insulating layer ISL-B. For example, the base insulating layer ISL-B may contain a small amount of carbon (C) atoms, and the buffer insulating layer LPD may include carbon (C) atoms corresponding to 5 times or more than carbon (C) atoms of the base insulating layer ISL-B.

According to an embodiment of the present disclosure, the base insulating layer ISL-B may be a layer including silicon nitride (SiNₓ), and the buffer insulating layer LPD disposed directly on the bottom surface of the base insulating layer ISL-B may be a layer including Si atoms and oxygen atoms. For example, the buffer insulating layer LPD may be a layer including silicon dioxide (SiO₂). In this case, the buffer insulating layer LPD may be formed under a CVD condition different from that of the base insulating layer ISL-B. For example, the buffer insulating layer LPD mainly including silicon dioxide (SiO₂) may be formed by using source gas different from that of the base insulating layer ISL-B mainly including the silicon nitride (SiNx). Even in this case, the buffer insulating layer LPD may be formed under a power condition lower than that of the base insulating layer ISL-B. Accordingly, the base insulating layer ISL-B may have a porosity that is higher than that of the base insulating layer ISL-B.

According to an embodiment of the present disclosure, each of the base insulating layer ISL-B and the buffer insulating layer LPD may further include an oxygen (O) atom. The base insulating layer ISL-B may further include an oxygen (O) atom in addition to the silicon nitride compound. The buffer insulating layer LPD may further include the oxygen (O) atom, which does not constitute the compound, in addition to the silicon dioxide (SiO₂). Even in this case, the percent of the oxygen (O) atom in the buffer insulating layer LPD may be 2 times to 100 times the percent of oxygen (O) atom in the base insulating layer ISL-B.

Further, even in this case, each of the base insulating layer ISL-B and the buffer insulating layer LPD may further include the carbon (C) atom, and the percent of carbon (C) atom in the buffer insulating layer LPD may be 2 times to 100 times the percent of the carbon (C) atom in the base insulating layer ISL-B. For example, the base insulating layer ISL-B may contain a small amount of carbon (C) atoms, and the buffer insulating layer LPD may include carbon (C) atoms corresponding to 5 times or more of carbon (C) atoms of the base insulating layer ISL-B.

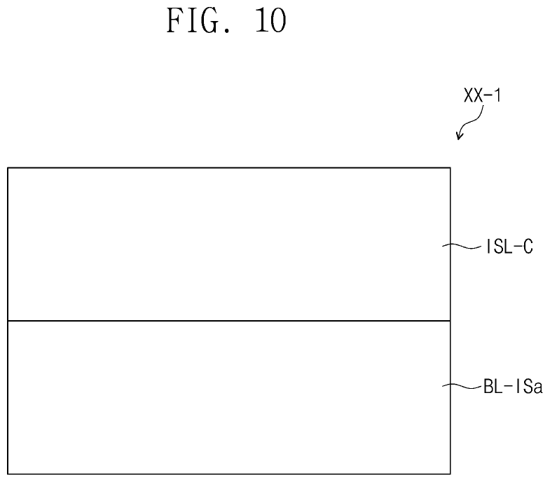

FIG. 10 is a cross-sectional view illustrating a portion of an input sensor according to an embodiment of the present disclosure. FIG. 10 illustrates an example corresponding to region ‘XX’ of FIG. 7. In FIG. 10, reference numeral “XX-1” is employed for an example corresponding to the region ‘XX’ of FIG. 7.

Referring to FIG. 10, according to an embodiment of the present disclosure, a sensor base layer BL-ISa may be provided in one single layer. For example, according to an embodiment of the present disclosure, the sensor base layer BL-ISa may be a single layer disposed directly under the sensor insulating layer ISL-C and may be a layer including oxygen (O) atoms in the range of 2 at % and 67 at %.

The sensor base layer BL-ISa may be referred to as a buffer insulating layer. According to an embodiment of the present disclosure, the sensor base layer BL-ISa may be a layer including a single layer of a buffer insulating layer.

The sensor base layer BL-ISa of a single layer of the buffer insulating layer may be a layer including SiO2 or may be a layer including silicon nitride (SiNX) and oxygen (O).

The percent of oxygen (O) atom in the sensor base layer BL-ISa, which is a single layer of the buffer insulating layer, may be 2 to 100 times the percent of oxygen (O) atom percent in the sensor insulating layer ISL-C. For example, the sensor insulating layer ISL-C may contain a small amount of oxygen (O) atoms, and the sensor base layer BL-ISa may contain 5 times or more of oxygen (O) atoms of the sensor insulating layer ISL-C. In addition, the sensor base layer BL-Isa and the sensor insulating layer ISL-C may further include carbon atoms. The percent of carbon (C) atom in the sensor base layer BL-ISa may be 2 to 100 times the percent of carbon (O) atom percent in the sensor insulating layer ISL-C. For example, the sensor insulating layer ISL-C may contain a small amount of carbon (C) atoms, and the sensor base layer BL-ISa may contain 5 times or more of carbon (C) atoms of the sensor insulating layer ISL-C.

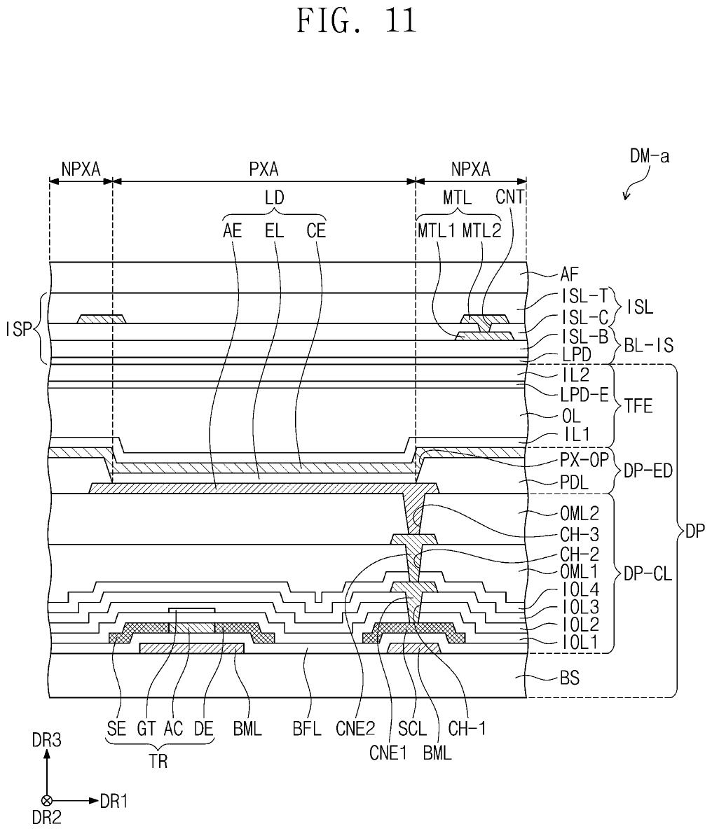

FIG. 11 is a cross-sectional view illustrating a portion of a display module according to an embodiment of the present disclosure. According to an embodiment illustrated in FIG. 11, a display module DM-a makes a difference in configuration of an encapsulation layer TFE-a from the display module DM according to an embodiment illustrated in FIG. 7.

According to an embodiment illustrated in FIG. 11, the encapsulation layer TFE-a may include the first inorganic film IL1, the organic film OL, the second inorganic film IL2 including SiNx, and an intermediate layer LPD-E interposed between the organic film OL and the second inorganic film IL2. The intermediate layer LPD-E may be interposed directly between the organic film OL and the second inorganic film IL2.

The second inorganic film IL2 may be formed through a CVD. Even the intermediate layer LPD-E may be formed through the CVD. The intermediate layer LPD-E may be formed through the CVD scheme under the same condition as a condition for forming the second inorganic film IL2 except for a power condition. The intermediate layer LPD-E may be treated by using the same source gas and plasma as those of the second inorganic film IL2. Regarding power, the intermediate layer LPD-E may be formed with power corresponding to 35% or less of the power of the second inorganic film IL2.

The intermediate layer LPD-E may be a layer including Si, N, O, and C. The intermediate layer LPD-E may be a layer having a higher content of oxygen (O) atoms, when compared to the content of oxygen (O) atoms in the second inorganic film IL2. For example, the intermediate layer LPD-E may be an inorganic oxide film.

The intermediate layer LPD-E may have a thickness less than that of the second inorganic film IL2. The thickness of the intermediate layer LPD-E may be within 10% of the thickness of the second inorganic film IL2.

The second inorganic film IL2 may further include oxygen and carbon, and the atomic percentage of oxygen (O) in the intermediate layer LPD-E may be 2 to 100 times the atomic percentage of oxygen (O) in the second inorganic film IL2. In addition, the atomic percentage of carbon (C) in the intermediate layer LPD-E may be twice or more and 100 times or less of the atomic percentage of carbon (C) in the second inorganic film IL2. For example, the intermediate layer LPD-E includes oxygen (O) atoms and carbon (C) atoms at an atomic percentage higher than that of the second inorganic film IL2. This is because the intermediate layer LPD-E includes oxygen (O) atoms and carbon (C) atoms resulting from reactants, impurities, or decomposition products introduced from the organic film OL under the intermediate layer LPD-E.

As the intermediate layer LPD-E is introduced, the coupling force between the second inorganic film IL2 and the organic film OL may be increased. Accordingly, the reliability of the display panel DP may be increased.

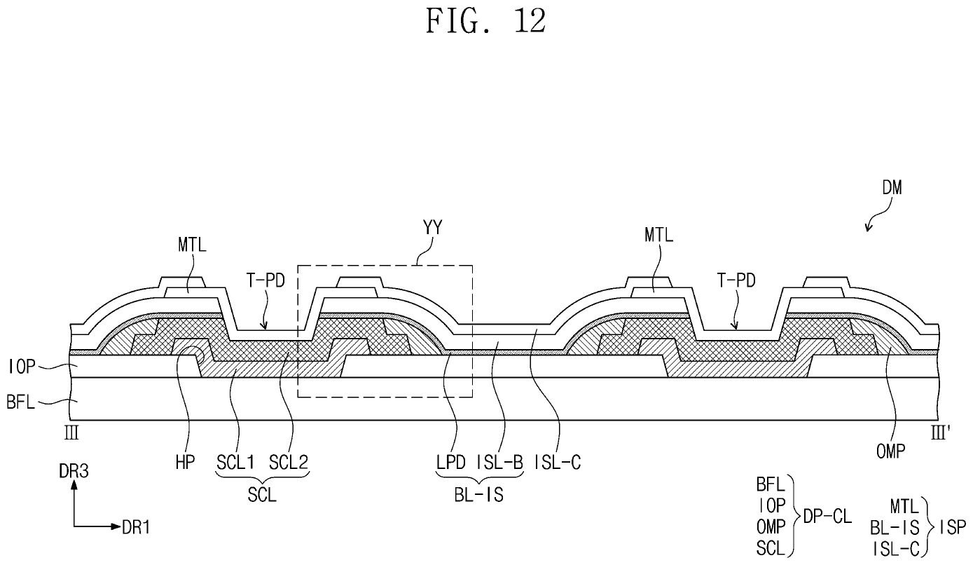

FIG. 12 is a cross-sectional view illustrating a portion of a display module according to an embodiment of the present disclosure. FIG. 12 is a cross-sectional view illustrating a part taken along line III-III′ of FIG. 6 in the display module. For example, FIG. 12 illustrates a portion of the peripheral region NAA (see FIG. 2) of the display module DM.

The non-sensing region NAA-S illustrated in FIG. 6 may correspond to the peripheral region NAA (see FIG. 2) of the display module DM. Referring to FIGS. 6 and 12, the peripheral region NAA (see FIG. 2) of the display module DM according to an embodiment may include the signal line SCL, an inorganic film pattern IOP, an organic film pattern OMP, the sensor conductive layer MTL, and the sensor base layer BL-IS.

The peripheral region NAA (see FIG. 2) includes the base layer BS (see FIG. 7), and may include the circuit layer DP-CL disposed on the base layer BS and including the inorganic film pattern IOP, the organic film pattern OMP, and the signal line SCL, and the input sensor ISP disposed on the circuit layer DP-CL and including the sensor base layer BL-IS, the sensor conductive layer MTL, and the sensor insulating layer ISL-C.

The display element layer DP-ED (see FIG. 7) and the encapsulation layer TFE (see FIG. 7) may be excluded from the peripheral region NAA (see FIG. 2). In addition, some of components of the circuit layer DP-CL illustrated in FIG. 7 may be excluded from the peripheral region NAA (see FIG. 2).

Referring to FIG. 12, the circuit layer DP-CL in the peripheral region may include the inorganic film pattern IOP in which a groove HP is defined, a signal line SCL disposed in the groove HP, and an organic film pattern OMP patterned to expose a portion of the top surface of the inorganic film pattern IOP while covering the edge of the signal line SCL.

The signal line SCL may be electrically connected to the transistor TR (see FIG. 7). In addition, referring to FIG. 12, the signal line SCL may include a first signal line SCL1 and a second signal line SCL2 stacked on each other in the third direction DR3 which is a thickness direction. The first signal line SCL1 and the second signal line SCL2 may be connected to mutually different transistors of a plurality of transistors included in the pixel PX (see FIG. 5).

The groove HP may be defined in the inorganic film pattern IOP. The signal line SCL may be disposed in the groove HP. An edge portion of the signal line SCL may be disposed on a top surface of the inorganic film pattern IOP. The inorganic film pattern IOP may be formed in the same process as at least one of the first to fourth insulating layers IOL1, IOL2, IOL3, and IOL4 of the circuit layer DP-CL illustrated in FIG. 7. For example, the inorganic film pattern IOP may be formed in the same process as at least one of the first to fourth insulating layers IOL1, IOL2, IOL3, and IOL4 of the circuit layer DP-CL illustrated in FIG. 7. The inorganic film pattern IOP may be formed on the same layer as any one of the first to fourth inorganic films. For example, the inorganic film pattern IOP may be formed in the same process as the first insulating layer IOL1 (or the first inorganic film), and the inorganic film pattern IOP may be positioned at the same layer as the first insulating layer IOL1.

The edge of the signal line SCL may be covered by the organic film pattern OMP. The organic film pattern OMP may be disposed on the inorganic film pattern IOP and may cover a side surface of the exposed signal line SCL. The organic film pattern OMP may be formed in the same process as at least one of the fifth insulating layer OML1 and the sixth insulating layer OML2 of the circuit layer DP-CL illustrated in FIG. 7. For example, the organic film pattern OMP may be formed in the same process as any one of the first organic film and the second organic film corresponding to the fifth insulating layer OML1 and the sixth insulating layer OML2, respectively. The organic film pattern OMP may be formed in the layer the same as the layer of any one organic film of the first organic film of the fifth insulating layer OML1 and the second organic film of the sixth insulating layer OML2. For example, the organic film pattern OMP may be formed in the same process as the sixth insulating layer OML2 (or the second organic film), and the organic film pattern OMP may be positioned in a layer the same as the sixth insulating layer OML2.

The input sensor ISP may be disposed on the circuit layer DP-CL. The input sensor ISP in the peripheral region NAA (see FIG. 2) may include the sensor base layer BL-IS, the sensor conductive layer MTL, and the first sensor insulating layer ISL-C. The input sensor ISP may further include the second sensor insulating layer ISL-T (see FIG. 7) disposed on the first sensor insulating layer ISL-C.

The sensor conductive layer MTL may be electrically connected to the signal line SCL in the groove HP of the inorganic film pattern IOP. The sensor conductive layer MTL exposed in the groove HP may be a part corresponding to the sensing pad T-PD.

The sensor conductive layer MTL may be electrically connected to the first sensing electrode TE1 (see FIG. 6) or the second sensing electrode TE2 (see FIG. 6). The sensor conductive layer MTL may be the first sensor conductive layer MTL1 or the second sensor conductive layer MTL2.

The sensor base layer BL-IS may cover the organic film pattern OMP. The sensor base layer BL-IS may be overlapped with only a portion of the signal line SCL. The most region of the signal line SCL disposed in the groove HP may not be overlapped with the sensor base layer BL-IS. The sensor base layer BL-IS may be interposed between the signal line SCL and the sensor conductive layer MTL. The sensor base layer BL-IS is interposed between the edge of the signal line SCL and the edge of the sensor conductive layer MTL, such that the edge of the signal line SCL and the edge of the sensor conductive layer MTL may be spaced apart from each other in the third direction DR3.

The sensor insulating layer ISL-C may be disposed on the sensor base layer BL-IS. The sensor insulating layer ISL-C may cover an edge of the sensor conductive layer MTL exposed on the sensor base layer BL-IS.

The sensor insulating layer ISL-C may be patterned and provided such that a portion of the sensor conductive layer MTL is exposed, and the sensing pad T-PD may be electrically connected to the flexible circuit film FCB (see FIG. 2) in a part not covered by the sensor insulating layer ISL-C. An anisotropic conductive film ACF may be disposed on the sensing pad T-PD, and the sensing pad T-PD and the flexible circuit film FCB (see FIG. 2) may be bonded to each other through the anisotropic conductive film ACF.

The description of the sensor base layer BL-IS made with reference to FIGS. 3 to 11 may be identically applied to the following description on the sensor base layer BL-IS. Referring to FIG. 12, the sensor base layer BL-IS may include the buffer insulating layer LPD and the base insulating layer ISL-B. The buffer insulating layer LPD may be interposed between the base insulating layer ISL-B and the organic film pattern OMP. The sensor base layer BL-IS may be a single layer. In this case, the sensor base layer BL-IS may be disposed, in the form of a single layer, under the sensor insulating layer ISL-C as illustrated in FIG. 10.

The buffer insulating layer LPD may have a higher porosity than the base insulating layer ISL-B. As the buffer insulating layer LPD has higher porosity, and thus may trap gas (outgas) emitted from the organic film pattern OMP disposed under the buffer insulating layer LPD, a by-product of the organic film pattern OMP, and a decomposition product. Accordingly, gas emitted from the lower organic film pattern OMP may be reduced from being transferred to the base insulating layer ISL-B, thereby reducing pressure applied to the base insulating layer ISL-B by impurities or gas.

The introduction of the buffer insulating layer LPD may increase the bonding force of the base insulating layer ISL-B. In addition, the buffer insulating layer LPD may increase the bonding force between the organic film pattern OMP and the base insulating layer ISL-B. Accordingly, the display module DM, according to an embodiment of the present disclosure, may exhibit high reliability characteristics.

In addition, even when pressure is provided to bond to the flexible circuit film FCB using the anisotropic conductive film ACF, the bonding force between the organic film pattern OMP and the base insulating layer ISL-B may be maintained by the buffer insulating layer LPD, such that the display module DM exhibits a high reliability characteristic.

According to an embodiment of the present disclosure, the buffer insulating layer LPD may have the higher content of oxygen (O) atoms when compared to the base insulating layer ISL-B and the sensor insulating layer ISL-C formed to include the silicon nitride (SiNx). For example, the percent of the oxygen (O) atom in the buffer insulating layer LPD may be 2 times to 100 times the percent of oxygen (O) atom in the base insulating layer ISL-B in the peripheral region NAA (see FIG. 2). For example, the base insulating layer ISL-B may contain a small amount of oxygen atoms, and the buffer insulating layer LPD may contain 5 times or more oxygen atoms than the base insulating layer ISL-B.

Each of the base insulating layer ISL-B and the buffer insulating layer LPD may further include a carbon (C) atom, and the atomic percentage of carbon (C) atoms in the buffer insulating layer LPD may be 2 to 100 times the atomic percentage of carbon (C) atoms in the base insulating layer ISL-B. For example, the base insulating layer ISL-B may contain a small amount of carbon (C) atoms, and the buffer insulating layer LPD may include carbon (C) atoms corresponding to 5 times or more of carbon (C) atoms of the base insulating layer ISL-B.

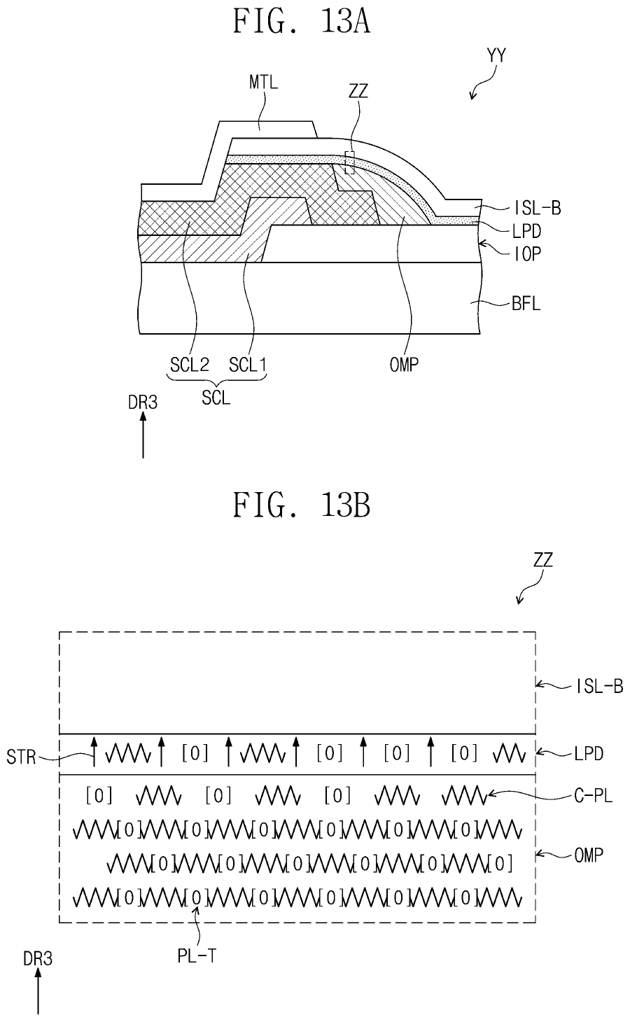

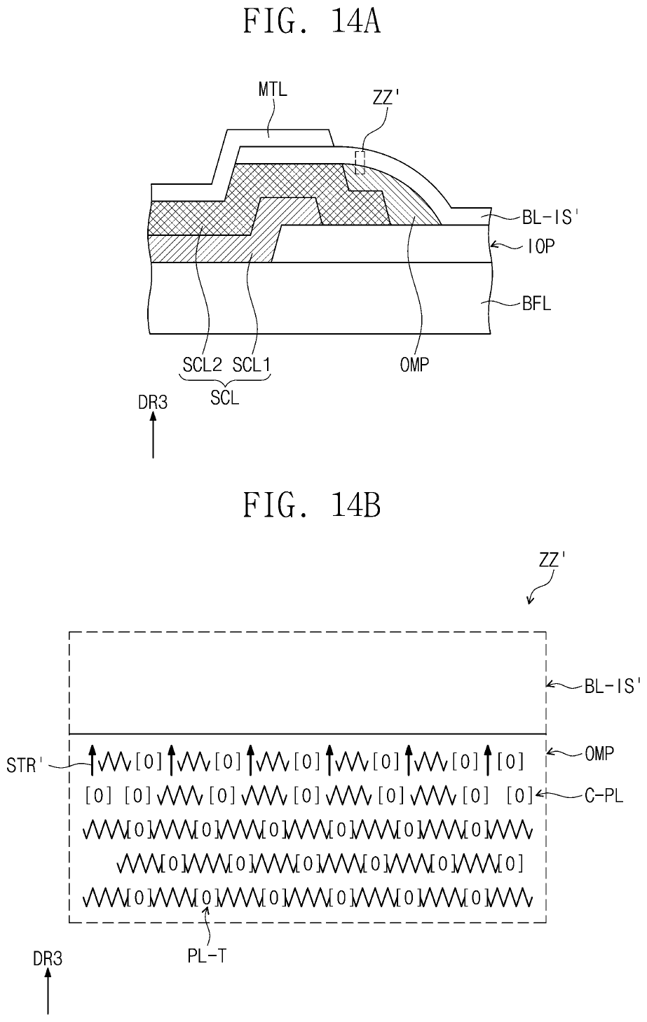

FIGS. 13A and 13B are views illustrating a portion of the input sensor. FIG. 13A is a cross-sectional view illustrating a part corresponding to region YY of FIG. 12, and FIG. 13B is an enlarged schematic view illustrating region ZZ of FIG. 13A. In addition, FIGS. 14A and 14B are views illustrating portions of a conventional input sensor without the buffer insulating layer. FIG. 14A is a cross-sectional view illustrating a part corresponding to the region YY of FIG. 13A, and FIG. 14B is an enlarged schematic view illustrating region ZZ′ of FIG. 14A.

Referring to FIGS. 13B and 14B, the organic film pattern OMP may include a polymer organic substance PL-T, and may include a remaining organic substance C-PL formed as the polymer organic substance PL-T is separated. The remaining organic substance C-PL may be decomposed into oxygen (O) and the form of hydrocarbon ( [symbol] ).

Referring to FIGS. 13A and 13B, according to an embodiment of the present disclosure, a portion of the remaining organic substance C-PL may be trapped into the buffer insulating layer LPD. For example, since the remaining organic substance C-PL may be stably positioned in the buffer insulating layer LPD having higher porosity, the pressure STR applied to the base insulating layer ISL-B may be relatively reduced by the remaining organic substance C-PL produced from the organic film pattern OMP.

For example, according to an embodiment of the present disclosure, the buffer insulating layer LPD may include oxygen and carbon produced from the organic film pattern OMP. Accordingly, the atomic content of oxygen (O) and carbon (C) may be higher than those of the base insulating layer ISL-B. Some remaining organic substances C-PL may be transmitted to the base insulating layer ISL-B, and may include oxygen and carbon.

Referring to FIGS. 14A and 14B, in the conventional display module, the remaining organic substance C-PL may be included in a sensor base layer BL-IS′ which does not include the buffer insulating layer. However, the sensor base layer BL-IS′ may be a layer formed of an inorganic material, and may have porosity lower than that of the buffer insulating layer LPD according to an embodiment of the present disclosure. Accordingly, the remaining organic substance C-PL is not sufficiently trapped in the sensor base layer BL-IS′, and a pressure STR′ may be excessively applied to the sensor base layer BL-IS′ by the remaining organic substance C-PL.

Accordingly, the remaining organic substance C-PL produced from the organic film pattern OMP applies the pressure STR′ to the sensor base layer BL-IS′. Accordingly, the bonding force between the organic film pattern OMP and the sensor base layer BL-IS′ may be reduced. Accordingly, the sensor base layer BL-IS′ may be detached.

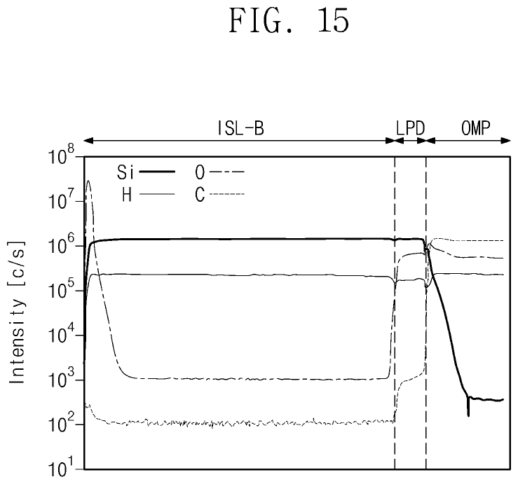

FIG. 15 illustrates the comparison of the atomic content in the part corresponding to region ZZ of FIG. 13A in terms of the relatively intensity. The intensity in FIG. 15 may correspond to the peak intensity of the atomic components by using an energy dispersive spectroscopy (EDS).

It may be recognized from FIG. 15 that the buffer insulating layer LPD has the higher carbon (C) content and the higher oxygen (O) content when compared to the base insulating layer ISL-B. For example, the buffer insulating layer LPD may include a remaining organic substance introduced from the organic film pattern OMP and may have the higher carbon (C) content and the higher oxygen (O) content when compared to the base insulating layer ISL-B.

According to an embodiment of the present disclosure, in the electronic device, the bonding force of the insulating layer to the adjacent layer may be increased by including the buffer insulating layer, which has a higher atomic percent of oxygen (O) than that of the insulating layer formed of the inorganic material, under the insulating layer formed of the inorganic material. In addition, according to an embodiment of the present disclosure, the electronic device may include the buffer insulating layer having higher porosity than that of the insulating layer formed of the inorganic material, under the insulating layer formed of the inorganic material, such that gas is trapped in the buffer insulating layer. Accordingly, the reliability and the bonding force of the insulating layer may be enhanced, such that the strong reliability may be shown.

In addition, according to an embodiment of the present disclosure, the electronic device includes the organic film pattern that covers the signal line in the peripheral region, the insulating layer disposed on the organic film pattern and formed of the inorganic material and the buffer insulating layer disposed under the insulating layer to cover the organic film pattern. Accordingly, the insulating layer effectively covers the organic film pattern and the bonding force is increased between the insulating layer and the organic film pattern, such that the strong reliability is shown.

According to an embodiment of the present disclosure, the electronic device includes the buffer insulating layer having the higher content of oxygen than that of the adjacent insulating layer, under the insulating layer including the inorganic material, thereby increasing the bonding force of the insulating layer, such that strong reliability is shown.

In addition, according to an embodiment of the present disclosure, the electronic device includes the buffer insulating layer, which has the higher content of oxygen (O) than that of the adjacent insulating layer, between the organic film pattern and the insulating layer including the inorganic material, thereby increasing the bonding force between the organic pattern and the insulating layer to effectively protect the signal line such that the strong reliability is shown. Although an embodiment of the present disclosure has been described for illustrative purposes, those skilled in the art will appreciate that various modifications, and substitutions are possible, without departing from the scope and spirit of the present disclosure . . .

What is claimed is:

1. An electronic device, comprising:
a base layer;
a circuit layer disposed on the base layer and including a transistor, a plurality of inorganic films, and a plurality of organic films;
a display element layer disposed on the circuit layer;
an encapsulation layer disposed on the display element layer; and
an input sensor disposed on the encapsulation layer and including a sensor base layer, a sensor conductive layer disposed on the sensor base layer, and a sensor insulating layer disposed on the sensor base layer, the sensor insulating layer including silicon nitride (SiNx),
wherein the sensor base layer includes:
a buffer insulating layer including silicon (Si) and oxygen (O), and
wherein an atomic percent of oxygen (O) within the buffer insulating layer is within a range of from 2 at % to 67 at %.

2. The electronic device of claim 1, wherein the sensor base layer further includes:
a base insulating layer including silicon nitride (SiNx), and
wherein the base insulating layer is disposed directly on the buffer insulating layer.

3. The electronic device of claim 2, wherein the base insulating layer further includes oxygen (O), and the buffer insulating layer further includes nitrogen (N), and
wherein an atomic percent of oxygen (O) in the buffer insulating layer is within a range of 2 times to 100 times of an atomic percent of oxygen (O) in the base insulating layer.

4. The electronic device of claim 2, wherein the sensor base layer has a thickness ranging from 1000 Å to 3000 Å, and
wherein the buffer insulating layer has a thickness ranging from 150 Å to 3000 Å.

5. The electronic device of claim 2, wherein the base insulating layer and the buffer insulating layer are each formed through a chemical vapor deposition (CVD) scheme, and
wherein a first power used to form the buffer insulating layer is 35% or less of a second power used to form the base insulating layer.

6. The electronic device of claim 2, wherein the buffer insulating layer has a porosity that is higher than a porosity of the base insulating layer.

7. The electronic device of claim 1, wherein the sensor base layer is a single layer of the buffer insulating layer including silicon dioxide (SiO₂).

8. The electronic device of claim 1, wherein the sensor base layer is a single layer of the buffer insulating layer including the silicon nitride (SiN_{X}) and oxygen (O).

9. The electronic device of claim 1, further comprising:
an active region and a peripheral region defined in at least one side of the active region,
wherein the peripheral region includes:
a signal line electrically connected to the transistor;
an inorganic film pattern formed on a same layer as one of the inorganic films is formed on, and the inorganic film pattern has a groove defined therein, wherein the signal line is disposed in the groove; and
an organic film pattern formed on a same layer as one of the organic films is formed on, and the organic film pattern covers an edge of the signal line not overlapping with the groove,
wherein the sensor conductive layer is electrically connected to the signal line in the groove, and
wherein the sensor base layer is disposed under the sensor conductive layer, and the sensor base layer overlaps with each of the organic film pattern, a top surface of the signal line, and the inorganic film pattern.

10. The electronic device of claim 9, wherein the sensor base layer further includes a base insulating layer including silicon nitride (SiNx), and
wherein the buffer insulating layer is interposed directly between the organic film pattern and the base insulating layer.

11. The electronic device of claim 10,
wherein the base insulating layer further includes oxygen (O) and carbon (C),
wherein the buffer insulating layer further includes nitrogen (N) and carbon (C),
wherein the atomic percent of oxygen (O) in the buffer insulating layer is within a range from 2 times to 100 times the atomic percent of oxygen (O) in the base insulating layer, and
wherein the atomic percent of carbon (C) in the buffer insulating layer is within a range from 2 times to 100 the atomic percent of carbon (C) in the base insulating layer.

12. The electronic device of claim 9, wherein the buffer insulating layer is interposed directly between the organic film pattern and the sensor insulating layer.

13. The electronic device of claim 12, wherein the sensor insulating layer and the buffer insulating layer further includes carbon (C), and
wherein the atomic percent of carbon (C) in the buffer insulating layer is within a range from 2 times to 100 times the atomic percent of carbon (C) in the sensor insulating layer.

14. The electronic device of claim 1, wherein the encapsulation layer includes:
a first inorganic layer sequentially stacked on the display element layer;
an organic layer disposed on the first inorganic layer;
a second inorganic layer disposed on the organic layer and including silicon nitride (SiNx); and
an intermediate layer interposed directly between the organic layer and the second inorganic layer and including silicon (Si), nitrogen (N), oxygen (O), and carbon (C).

15. The electronic device of claim 14, wherein the second inorganic layer further includes oxygen (O) and carbon (C),
wherein the atomic percent of oxygen (O) in the intermediate layer is within a range of 2 times to 100 times the atomic percent of oxygen (O) in the second inorganic layer, and
wherein the atomic percent of carbon (C) in the intermediate layer is within a range of 2 times to 100 times the atomic percent of carbon (C) in the second inorganic layer.

16. The electronic device of claim 14, wherein the sensor base layer is disposed directly on the second inorganic layer.

17. An electronic device, comprising:
an active region and a peripheral region disposed on at least one side of the active region,
wherein the peripheral region includes:
a base layer;
a circuit layer disposed on the base layer, the circuit layer including an inorganic film pattern having a groove defined in, a signal line disposed in the groove, and an organic film pattern covering an edge of the signal line and exposing a portion of a top surface of the inorganic film pattern; and
an input sensor disposed on the circuit layer, the input sensor including a sensor conductive layer electrically connected to the signal line, a sensor base layer covering the organic film pattern and the exposed top surface of the inorganic film pattern, and a sensor insulating layer disposed on the sensor base layer, and
wherein the sensor base layer includes a buffer insulating layer including silicon (Si) and oxygen (O), and an atomic percent of oxygen (O) within the buffer insulating layer is in a range of 2 at % to 67 at %.

18. The electronic device of claim 17, wherein the sensor base layer includes SiNx and further includes a base insulating layer disposed under the sensor insulating layer, and
wherein the base insulating layer is disposed directly on the buffer insulating layer.

19. The electronic device of claim 18, wherein the sensor base layer has a thickness ranging from 1000 Å to 3000 Å, and
wherein the buffer insulating layer has a thickness ranging from 150 Å to 3000 Å.

20. The electronic device of claim 18, wherein the base insulating layer further includes oxygen (O) and carbon (C), and the buffer insulating layer further includes nitrogen (N), and carbon (C),
wherein the atomic percent of oxygen (O) in the buffer insulating layer is 2 times to 100 times the atomic percent of oxygen (O) in the base insulating layer, and
wherein the atomic percent of carbon (C) in the buffer insulating layer is 2 times to 100 times the atomic percent of carbon (C) in the base insulating layer.

21. The electronic device of claim 17, wherein the sensor base layer is a single layer including the buffer insulating layer, and
wherein the buffer insulating layer includes SiO₂, or includes SiN_{X} and O.

22. The electronic device of claim 17, wherein the active region further includes:
a display element layer interposed between the circuit layer and the input sensor, and the display element layer includes a light emitting element; and
an encapsulation layer disposed on the display element layer, and
wherein the sensor base layer is disposed directly on the encapsulation layer in the active region.

23. The electronic device of claim 22, wherein, in the active region, the circuit layer includes:
an inorganic film formed in a same process as the inorganic film pattern;
an organic film formed in a same process as the organic film pattern; and
a transistor electrically connected to the signal line.

24. An electronic device, comprising:
a base layer;
a circuit layer disposed on the base layer and including a transistor, a plurality of inorganic films, and a plurality of organic films;
a display element layer disposed on the circuit layer;
an encapsulation layer disposed on the display element layer; and
an input sensor disposed on the encapsulation layer and including a sensor base layer, a sensor conductive layer disposed on the sensor base layer, and a sensor insulating layer disposed on the sensor base layer and including silicon nitride (SiNx),
wherein the sensor base layer includes a buffer insulating layer including silicon (Si) and oxygen (O), and
wherein the buffer insulating layer has a porosity that is higher than a porosity of the sensor insulating layer.

25. The electronic device of claim 24, wherein the sensor base layer further includes a base insulating layer disposed directly over the buffer insulating layer and including SiNx, and
wherein the porosity of the buffer insulating layer is greater than a porosity of the sensor base layer.

26. The electronic device of claim 25, wherein the base insulating layer and the buffer insulating layer are formed through a chemical vapor deposition (CVD) scheme, and
wherein a first power used to form the buffer insulating layer is 35% or less of a second power used to form the base insulating layer.

27. The electronic device of claim 25, wherein the base insulating layer further includes oxygen (O), and the buffer insulating layer further includes nitrogen (N), and
wherein the atomic percent of oxygen (O) in the buffer insulating layer is 2 times to 100 times the atomic percent of oxygen (O) in the base insulating layer.

28. The electronic device of claim 25, wherein the sensor base layer has a thickness ranging from 1000 Å to 3000 Å, and
wherein the buffer insulating layer has a thickness ranging from 150 Å to 3000 Å.
